(19) United States
(12) Patent Application Publication
(10) Pub. No.: US 2024/0029636 A1
(43) Pub. Date: Jan. 25, 2024

(54) Display Apparatus And Electronic Device

(71) Applicant: Semiconductor Energy Laboratory Co., Ltd., Kanagawa-ken (JP)

(72) Inventors: Shunpei YAMAZAKI, Setagaya, Tokyo (JP); Takayuki IKEDA, Atsugi, Kanagawa (JP); Hajime KIMURA, Atsugi, Kanagawa (JP); Tatsuya ONUKI, Atsugi, Kanagawa (JP)

(73) Assignee: Semiconductor Energy Laboratory Co., Ltd., Kanagawa-ken (JP)

(21) Appl. No.: 18/265,539

(22) PCT Filed: Nov. 29, 2021
(86) PCT No.: PCT/IB2021/061035

§ 371 Date: Jun. 6, 2023

(30) Foreign Application Priority Data
Dec. 11, 2020 (JP) 2020-206259

(51) Int. Cl. G09G 3/32; H10K 59/121

(52) U.S. Cl. CPC G09G 3/32; H10K 59/1213; G09G 2300/0465; G09G 2300/0452; G09G 2320/0666; G09G 2300/0842

(57) ABSTRACT

A novel display apparatus is provided. The display apparatus includes a display portion and a peripheral circuit for driving the display portion, and the display portion is provided to overlap with and above the peripheral circuit. The display portion include a plurality of pixels arranged in a matrix, and the plurality of pixels each have a function of emitting light. The peripheral circuit includes a first transistor, and the pixel includes a second transistor. A semiconductor layer included in the first transistor and a semiconductor layer included in the second transistor are formed using materials having different compositions.

### TECHNICAL FIELD

One embodiment of the present invention relates to a display apparatus. One embodiment of the present invention relates to a method for manufacturing a display apparatus. Note that one embodiment of the present invention is not limited to the above technical field. Examples of the technical field of one embodiment of the present invention disclosed in this specification and the like include a semiconductor device, a display apparatus, a light-emitting apparatus, a power storage device, a memory device, an electronic device, a lighting device, an input device, an input/output device, a driving method thereof, and a manufacturing method thereof.

### BACKGROUND ART

In recent years, higher resolution of display apparatuses have been desired. For example, devices for virtual reality (VR), augmented reality (AR), substitutional reality (SR), or mixed reality (MR) are given as devices requiring high-resolution display apparatuses and have been actively developed in recent years. Display apparatuses used for these devices are required to be downsized as well as to increase resolution.

Typical examples of the display apparatus include a liquid crystal display apparatus; a light-emitting apparatus including a light-emitting element such as an organic electroluminescent (EL) element or a light-emitting diode (LED); and electronic paper performing display by an electrophoretic method or the like.

For example, the basic structure of an organic EL element is a structure in which a layer containing a light-emitting organic compound is provided between a pair of electrodes. By voltage application to this element, light emission can be obtained from the light-emitting organic compound. A display apparatus using such an organic EL element does not need a backlight that is necessary for a liquid crystal display apparatus and the like; thus, a thin, lightweight, high-contrast, and low-power consumption display apparatus can be achieved. Patent Document 1, for example, discloses an example of a display apparatus using an organic EL element.

### REFERENCE

### Patent Document

[Patent Document 1] Japanese Published Patent Application No. 2002-324673

### SUMMARY OF THE INVENTION

### Problems to be Solved by the Invention

In general, a display apparatus includes a display portion including a plurality of pixels and a peripheral driver circuit portion for supplying image signals to a display region. The driver circuit portion is provided in the peripheral portion of the display region.

An object of one embodiment of the present invention is to provide a display apparatus with high emission luminance. An object of one embodiment of the present invention is to provide a small display apparatus. An object of one embodiment of the present invention is to provide a display apparatus in which high color reproducibility is achieved. An object of one embodiment of the present invention is to provide a high-resolution display apparatus. An object of one embodiment of the present invention is to provide a highly reliable display apparatus. An object of one embodiment of the present invention is to provide a novel display apparatus.

Note that the description of these objects does not preclude the existence of other objects. One embodiment of the present invention does not have to achieve all the objects. Note that objects other than these can be derived from the descriptions of the specification, the drawings, the claims, and the like.

### Means for Solving the Problems

One embodiment of the present invention is a display apparatus including a display portion and a peripheral circuit portion that drives the display portion. The display portion and the peripheral circuit portion have a region overlapping with each other, the display portion includes a plurality of pixels arranged in matrix, the peripheral circuit portion includes a first transistor, the pixel includes a second transistor, and a composition of a first semiconductor layer included in the first transistor is different from a composition of a second semiconductor layer included in the second transistor.

The peripheral circuit portion includes, for example, a scan line driver circuit and a signal line driver circuit. The plurality of pixels each have a function of emitting light, and the light is preferably emitted in a direction in which the peripheral circuit portion is not formed. The pixel may include an EL element, for example.

The first semiconductor layer may be a single crystal semiconductor or a polycrystalline semiconductor. The second semiconductor layer may be an oxide semiconductor. For example, the first semiconductor layer may be formed using single crystal silicon and the second semiconductor layer may be formed using an oxide containing at least one of indium and zinc.

### Effect of the Invention

One embodiment of the present invention can provide a display apparatus with high emission luminance. Another embodiment of the present invention can provide a downsized display apparatus. Alternatively, a display apparatus in which high color reproducibility is achieved can be provided. Alternatively, a high-resolution display apparatus can be provided. In addition, a highly reliable display apparatus can be provided. Alternatively, a method for manufacturing the above-described display apparatus can be provided.

Note that the description of these effects does not preclude the existence of other effects. One embodiment of the present invention does not need to have all of these effects. Note that effects other than these can be derived from the descriptions of the specification, the drawings, the claims, and the like.

### BRIEF DESCRIPTION OF THE DRAWINGS

FIG. 1A to FIG. 1C are diagrams illustrating a structure example of a display apparatus.

FIG. 2A and FIG. 2B1 to FIG. 2B5 are diagrams illustrating a structure example of a display apparatus.

FIG. 3A to FIG. 3C are diagrams illustrating configuration examples of a pixel circuit.

FIG. 4 is a diagram illustrating a structure example of a display apparatus.

FIG. 5A to FIG. 5F are diagrams illustrating an example of a method for manufacturing a display apparatus.

FIG. 6A to FIG. 6G are diagrams illustrating an example of a method for manufacturing a display apparatus.

FIG. 7A and FIG. 7B are diagrams illustrating an example of a method for manufacturing a display apparatus.

FIG. 8A and FIG. 8B are diagrams illustrating an example of a method for manufacturing a display apparatus.

FIG. 9A to FIG. 9C are diagrams illustrating an example of a method for manufacturing a display apparatus.

FIG. 10A is a diagram showing classification of crystal structures. FIG. 10B is a diagram showing an XRD spectrum of a CAAC-IGZO film. FIG. 10C is a diagram showing nanobeam electron diffraction patterns of the CAAC-IGZO film.

FIG. 11A and FIG. 11B are diagrams illustrating a structure example of a display module.

FIG. 12A and FIG. 12B are views illustrating a structure example of a display module.

FIG. 13A and FIG. 13B are layout diagrams of display apparatuses manufactured using a 12-inch wafer.

FIG. 14A to FIG. 14C are diagrams illustrating structure examples of light-emitting elements.

FIG. 15A and FIG. 15B are diagrams illustrating a structure example of an electronic device.

FIG. 16A to FIG. 16D are diagrams illustrating structure examples of electronic devices.

### MODE FOR CARRYING OUT THE INVENTION

Hereinafter, embodiments will be described with reference to the drawings. Note that the embodiments can be implemented in many different modes, and it is readily understood by those skilled in the art that modes and details thereof can be changed in various ways without departing from the spirit and scope thereof. Thus, the present invention should not be interpreted as being limited to the following description of the embodiments.

In this specification and the like, a semiconductor device refers to a device that utilizes semiconductor characteristics, and means a circuit including a semiconductor element (e.g., a transistor, a diode, or a photodiode), a device including the circuit, and the like. The semiconductor device also means all devices that can function by utilizing semiconductor characteristics. For example, an integrated circuit, a chip including an integrated circuit, and an electronic component including a chip in a package are examples of the semiconductor device. Moreover, a memory device, a display apparatus, a light-emitting apparatus, a lighting device, an electronic device, and the like themselves may be semiconductor devices or may each include a semiconductor device.

In the case where there is description “X and Y are connected” in this specification and the like, the case where X and Y are electrically connected, the case where X and Y are functionally connected, and the case where X and Y are directly connected are regarded as being disclosed in this specification and the like. Accordingly, without being limited to a predetermined connection relationship, for example, a connection relationship shown in drawings or texts, a connection relationship other than one shown in drawings or texts is regarded as being disclosed in the drawings or the texts. Each of X and Y denotes an object (e.g., a device, an element, a circuit, a wiring, an electrode, a terminal, a conductive film, or a layer).

For example, in the case where X and Y are electrically connected, one or more elements that allow electrical connection between X and Y (e.g., a switch, a transistor, a capacitor, an inductor, a resistor, a diode, a display device, a light-emitting device, and a load) can be connected between X and Y. Note that a switch is controlled to be in an on state or an off state. That is, a switch has a function of controlling whether or not current flows by being in a conduction state (on state) or a non-conduction state (off state).

For example, in the case where X and Y are functionally connected, one or more circuits that allow functional connection between X and Y (e.g., a logic circuit (an inverter, a NAND circuit, a NOR circuit, or the like); a signal converter circuit (a digital-analog converter circuit, an analog-digital converter circuit, a gamma correction circuit, or the like); a potential level converter circuit (a power supply circuit (a step-up circuit, a step-down circuit, or the like), a level shifter circuit for changing the potential level of a signal, or the like); a voltage source; a current source; a switching circuit; an amplifier circuit (a circuit that can increase signal amplitude, the amount of current, or the like, an operational amplifier, a differential amplifier circuit, a source follower circuit, a buffer circuit, or the like); a signal generation circuit; a memory circuit; a control circuit; or the like) can be connected between X and Y. For instance, even if another circuit is interposed between X and Y, X and Y are regarded as being functionally connected when a signal output from X is transmitted to Y.

Note that an explicit description that X and Y are electrically connected includes the case where X and Y are electrically connected (i.e., the case where X and Y are connected with another element or another circuit interposed therebetween) and the case where X and Y are directly connected (i.e., the case where X and Y are connected without another element or another circuit interposed therebetween).

It can be expressed as, for example, “X, Y, a source (or a first terminal or the like) of a transistor, and a drain (or a second terminal or the like) of the transistor are electrically connected to each other, and X, the source (or the first terminal or the like) of the transistor, the drain (or the second terminal or the like) of the transistor, and Y are electrically connected to each other in this order”. Alternatively, it can be expressed as “a source (or a first terminal or the like) of a transistor is electrically connected to X, a drain (or a second terminal or the like) of the transistor is electrically connected to Y, and X, the source (or the first terminal or the like) of the transistor, the drain (or the second terminal or the like) of the transistor, and Y are electrically connected to each other in that order”. Alternatively, it can be expressed as “X is electrically connected to Y through a source (or a first terminal or the like) and a drain (or a second terminal or the like) of a transistor, and X, the source (or the first terminal or the like) of the transistor, the drain (or the second terminal or the like) of the transistor, and Y are provided in this connection order”. When the connection order in a circuit configuration is defined by an expression similar to the above examples, a source (or a first terminal or the like) and a drain (or a second terminal or the like) of a transistor can be distinguished from each other to specify the technical scope. Note that these expressions are examples and the expression is not limited to these expressions. Here, X and Y each denote an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has functions of both components: a function of the wiring and a function of the electrode. Thus, electrical connection in this specification includes, in its category, such a case where one conductive film has functions of a plurality of components.

In this specification and the like, a “capacitor” can be, for example, a circuit element having an electrostatic capacitance value higher than 0 F, a region of a wiring having an electrostatic capacitance value higher than 0 F, parasitic capacitance, or gate capacitance of a transistor. Therefore, in this specification and the like, a “capacitor” includes not only a circuit element that has a pair of electrodes and a dielectric between the electrodes, but also parasitic capacitance generated between wirings, gate capacitance generated between a gate and one of a source and a drain of a transistor, and the like. The terms “capacitor”, “parasitic capacitance”, “gate capacitance”, and the like can be replaced with the term “capacitance” and the like; conversely, the term “capacitance” can be replaced with the terms “capacitor”, “parasitic capacitance”, “gate capacitance”, and the like. The term “a pair of electrodes” of a “capacitor” can be replaced with “a pair of conductors”, “a pair of conductive regions”, “a pair of regions”, and the like. Note that the electrostatic capacitance value can be higher than or equal to 0.05 fF and lower than or equal to 10 pF, for example. As another example, the electrostatic capacitance value may be higher than or equal to 1 pF and lower than or equal to 10 μF.

In this specification and the like, a transistor includes three terminals called a gate, a source, and a drain. The gate is a control terminal for controlling the conduction state of the transistor. Two terminals functioning as the source and the drain are input/output terminals of the transistor. One of the two input/output terminals serves as the source and the other serves as the drain depending on the conductivity type (n-channel type or p-channel type) of the transistor and the levels of potentials applied to the three terminals of the transistor. Thus, the terms “source” and “drain” can be replaced with each other in this specification and the like. Furthermore, in this specification and the like, expressions “one of a source and a drain” (or a first electrode or a first terminal) and “the other of the source and the drain” (or a second electrode or a second terminal) are used in the description of the connection relation of a transistor. Depending on the transistor structure, a transistor may include a back gate in addition to the above three terminals. In that case, in this specification and the like, one of the gate and the back gate of the transistor may be referred to as a first gate and the other of the gate and the back gate of the transistor may be referred to as a second gate. Moreover, the terms “gate” and “back gate” can be replaced with each other in one transistor in some cases. In the case where a transistor includes three or more gates, the gates may be referred to as a first gate, a second gate, and a third gate, for example, in this specification and the like.

In this specification and the like, a “node” can be referred to as a terminal, a wiring, an electrode, a conductive layer, a conductor, an impurity region, or the like depending on the circuit configuration, the device structure, or the like. Furthermore, a terminal, a wiring, or the like can be referred to as a “node.”

Ordinal numbers such as “first”, “second”, and “third” in this specification and the like are used to avoid confusion among components. Thus, the ordinal numbers do not limit the number of components. In addition, the ordinal numbers do not limit the order of components. For example, a “first” component in one embodiment in this specification and the like can be referred to as a “second” component in other embodiments, the scope of claims, or the like. Furthermore, for example, a “first” component in one embodiment in this specification and the like can be omitted in other embodiments, the scope of claims, or the like.

In this specification and the like, terms for describing arrangement, such as “over”, “under”, “above”, and “below” are sometimes used for convenience to describe the positional relation between components with reference to drawings. The positional relation between components is changed as appropriate in accordance with a direction in which each component is described. Thus, the positional relation is not limited to the terms described in the specification and the like, and can be described with another term as appropriate depending on the situation. For example, the expression “an insulator positioned over (on) a top surface of a conductor” can be replaced with the expression “an insulator positioned under (on) a bottom surface of a conductor” when the direction of a drawing illustrating these components is rotated by 180°.

The term “over” or “under” does not necessarily mean that a component is placed directly over or directly under and directly in contact with another component. For example, the expression “electrode B over insulating layer A” does not necessarily mean that the electrode B is formed over and in direct contact with the insulating layer A, and does not exclude the case where another component is provided between the insulating layer A and the electrode B.

In this specification and the like, the terms “film”, “layer”, and the like can be interchanged with each other depending on the situation. For example, the term “conductive layer” can be changed into the term “conductive film” in some cases. As another example, the term “insulating film” can be changed into the term “insulating layer” in some cases. Alternatively, the term “film,” “layer,” or the like is not used and can be interchanged with another term depending on the case or the situation. For example, the term “conductive layer” or “conductive film” can be changed into the term “conductor” in some cases. Furthermore, for example, the term “insulating layer” or “insulating film” can be changed into the term “insulator” in some cases.

In addition, in this specification and the like, the term such as “electrode,” “wiring,” or “terminal” does not limit the function of a component. For example, an “electrode” is used as part of a wiring in some cases, and vice versa. Furthermore, the term “electrode” or “wiring” also includes the case where a plurality of “electrodes” or “wirings” are formed in an integrated manner, for example. For example, a “terminal” is used as part of a “wiring” or an “electrode” in some cases, and vice versa. Furthermore, the term “terminal” also includes the case where a plurality of “electrodes”, “wirings”, “terminals”, or the like are formed in an integrated manner, for example. Therefore, for example, an “electrode” can be part of a “wiring” or a “terminal”, and a “terminal” can be part of a “wiring” or an “electrode”. Moreover, the term “electrode”, “wiring”, “terminal”, or the like is sometimes replaced with the term “region”, for example.

In addition, in this specification and the like, the term such as “wiring,” “signal line,” or “power supply line” can be interchanged with each other depending on the case or the situation. For example, the term “wiring” can be changed into the term “signal line” in some cases. As another example, the term “wiring” can be changed into the term “power supply line” or the like in some cases. Conversely, the term such as “signal line” or “power supply line” can be changed into the term “wiring” in some cases. The term “power supply line” or the like can be changed into the term “signal line” or the like in some cases. Conversely, the term “signal line” or the like can be changed into the term “power supply line” or the like in some cases. Moreover, the term “potential” that is applied to a wiring can be sometimes changed into the term such as “signal” depending on the case or the situation. Conversely, the term “signal” or the like can be changed into the term “potential” in some cases.

In this specification, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 85° and less than or equal to 95° is also included. Furthermore, “approximately perpendicular” or “substantially perpendicular” indicates a state where two straight lines are placed at an angle greater than or equal to 60° and less than or equal to 120°.

Embodiments described in this specification are described with reference to the drawings. Note that the embodiments can be implemented in many different modes, and it will be readily understood by those skilled in the art that the modes and details can be changed in various ways without departing from the spirit and scope thereof. Therefore, the present invention should not be interpreted as being limited to the description in the embodiments. Note that in the structures of the invention in the embodiments, the same reference numerals are used in common for the same portions or portions having similar functions in different drawings, and repeated description thereof is omitted in some cases. Moreover, some components are omitted in a perspective view, a top view, and the like for easy understanding of the diagrams in some cases.

In addition, in the drawings in this specification, the size, the layer thickness, or the region is exaggerated for clarity in some cases. Therefore, embodiments of the present invention are not limited to the size, aspect ratio, and the like illustrated in the drawings. Note that the drawings schematically illustrate ideal examples, and embodiments of the present invention are not limited to shapes, values, and the like illustrated in the drawings. For example, variation in signal, voltage, or current due to noise or variation in signal, voltage, or current due to difference in timing can be included.

Note that in structures of the invention described below, the same portions or portions having similar functions are denoted by the same reference numerals in different drawings, and the description thereof is not repeated. Furthermore, the same hatch pattern is used for the portions having similar functions, and the portions are not especially denoted by reference numerals in some cases.

### Embodiment 1

In this embodiment, a display apparatus of one embodiment of the present invention and a method for manufacturing the display apparatus will be described.

### <Structure Example of Display Apparatus 100>

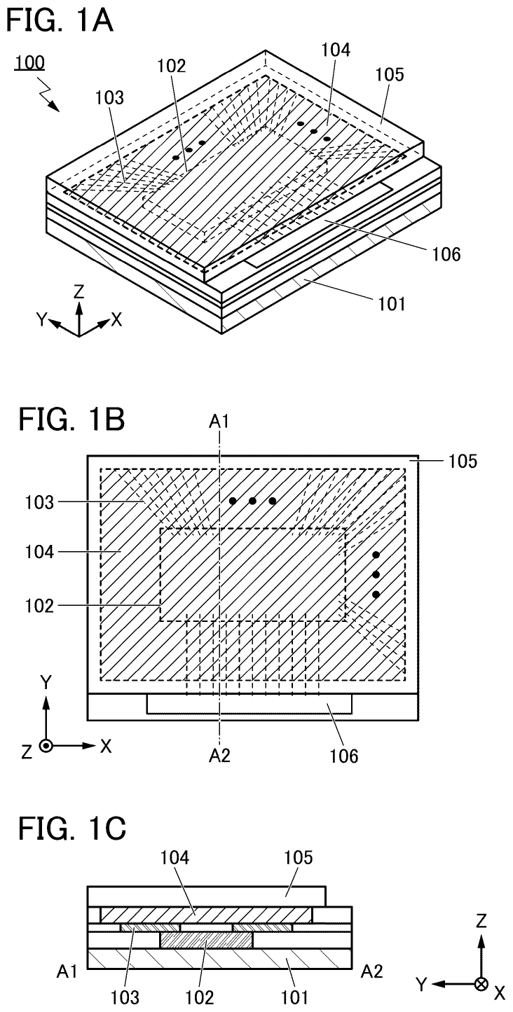

FIG. 1A is a perspective view of a display apparatus 100 of one embodiment of the present invention. FIG. 1B is a top view of the display apparatus 100. FIG. 1C is a cross-sectional view of a portion indicated by dashed-dotted line A1-A2 in FIG. 1B.

The display apparatus 100 includes, over a substrate 101, a driver circuit 102, which is one kind of semiconductor devices, and a display portion 104 over the driver circuit 102. The driver circuit 102 and the display portion 104 have a region overlapping with each other. A wiring group 103 is provided between the driver circuit 102 and the display portion 104. The driver circuit 102 and the display portion 104 are electrically connected to each other through the wiring group 103. The driver circuit 102 is electrically connected to an input-output terminal portion 106. The display apparatus 100 includes a substrate 105 over the display portion 104.

Note that arrows indicating the X direction, the Y direction, and the Z direction are illustrated in drawings. In this specification and the like, the “X direction” is a direction along the X-axis, and the forward direction and the reverse direction are not distinguished in some cases, unless otherwise specified. The same applies to the “Y direction” and the “Z direction”. The X direction, the Y direction, and the Z direction are directions intersecting with each other. More specifically, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases. In FIG. 1 and the like, a direction perpendicular to a surface of the substrate 101 is the Z direction.

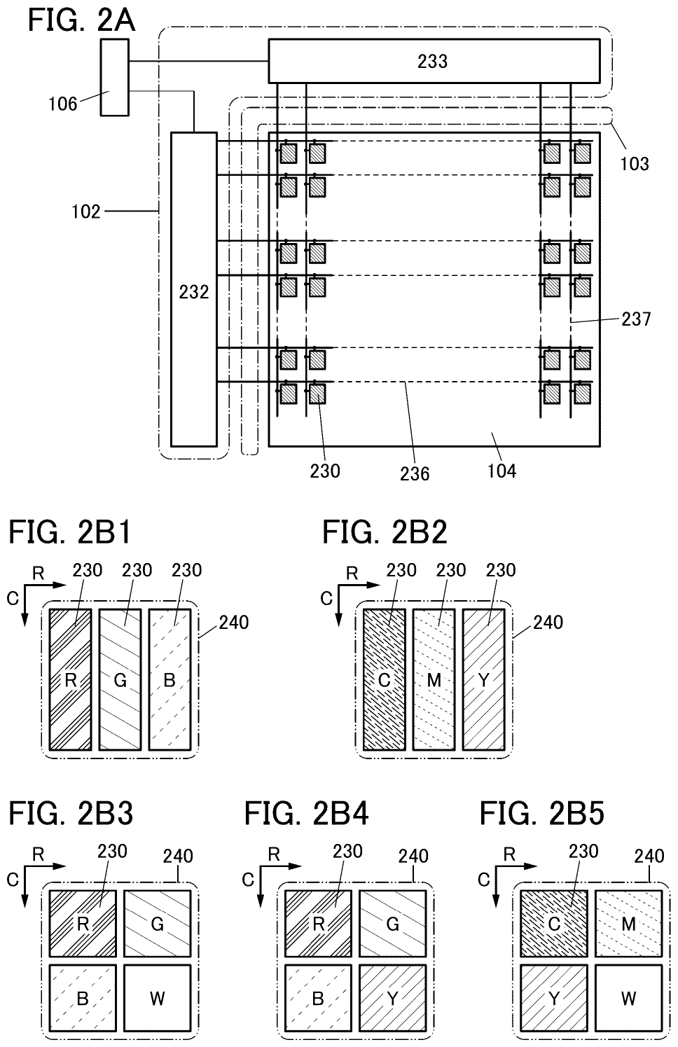

FIG. 2A is a block diagram illustrating a connection relation between the driver circuit 102 and the display portion 104.

The driver circuit 102 includes a first driver circuit 232 and a second driver circuit 233. The driver circuit 102 is electrically connected to the input-output terminal portion 106. A circuit included in the first driver circuit 232 functions as, for example, a scan line driver circuit. A circuit included in the first driver circuit 232 functions as, for example, a signal line driver circuit. Some sort of circuit may be provided to face the first driver circuit 232 with the display portion 104 placed therebetween. Some sort of circuit may be provided to face the second driver circuit 233 with the display portion 104 placed therebetween.

The driver circuit 102 is referred to as a “peripheral driver circuit” in some cases. Various circuits such as a shift register, a level shifter, an inverter, a latch, an analog switch, and a logic circuit can be used as the peripheral driver circuit. In the peripheral driver circuit, a transistor, a capacitor, or the like can be used.

The display apparatus 100 includes m wirings 236 (m is an integer of 1 or more) which are arranged substantially parallel to each other and whose potentials are controlled by the circuit included in the first driver circuit 232, and n wirings 237 (n is an integer of 1 or more) which are arranged substantially parallel to each other and whose potentials are controlled by the circuit included in the second driver circuit 233. The wiring 236 is electrically connected to the first driver circuit 232 through a part of the wiring group 103. The wiring 237 is electrically connected to the second driver circuit 233 through a part of the wiring group 103.

The display portion 104 includes a plurality of pixels 230 arranged in a matrix. Full-color display can be achieved by making the pixel 230 that controls red light, the pixel 230 that controls green light, and the pixel 230 that controls blue light collectively function as one pixel 240 and by controlling the amount of light (emission luminance) emitted from each pixel 230. Thus, the three pixels 230 each function as a sub-pixel. That is, three sub-pixels each control the amount or the like of emission light, such as red light, green light, or blue light (see FIG. 2B1). The light colors controlled by the three sub-pixels are not limited to a combination of red (R), green (G), and blue (B) and may be cyan (C), magenta (M), and yellow (Y) (see FIG. 2B2).

Four sub-pixels may collectively function as one pixel. For example, a sub-pixel that controls white light (W) may be added to the three sub-pixels that control red light, green light, and blue light (see FIG. 2B3). The addition of the sub-pixel that controls white light can increase the luminance of a display region. Alternatively, a sub-pixel that controls yellow light may be added to the three sub-pixels that control red light, green light, and blue light (see FIG. 2B4). Alternatively, a sub-pixel that controls white light may be added to the three sub-pixels that control cyan light, magenta light, and yellow light (see FIG. 2B5).

When the number of sub-pixels functioning as one pixel is increased and sub-pixels that control light of red, green, blue, cyan, magenta, yellow, and the like are combined as appropriate, the reproducibility of halftones can be increased. Therefore, the color reproducibility can be improved.

The display apparatus according to one embodiment of the present invention can reproduce the color gamut of various standards. For example, the display apparatus according to one embodiment of the present invention can reproduce the color gamut of the PAL (Phase Alternating Line) standard and the NTSC (National Television System Committee) standard used for TV broadcasting; the sRGB (standard RGB) standard and the Adobe RGB standard widely used for display apparatuses used in electronic devices such as personal computers, digital cameras, and printers; the ITU-R BT.709 (International Telecommunication Union Radiocommunication Sector Broadcasting Service (Television) 709) standard used for HDTV (High Definition Television, also referred to Hi-Vision); the DCI-P3 (Digital Cinema Initiatives P3) standard used for digital cinema projection; the ITU-R BT.2020 (REC.2020 (Recommendation 2020)) standard used for UHDTV (Ultra High Definition Television, also referred to as Super Hi-Vision); and the like.

Using the pixels 240 arranged in a matrix of 1920×1080, the display apparatus 100 can achieve full color display with a resolution of a so-called full hi-vision (also referred to as 2K resolution, 2K1K, 2K, or the like). For example, using the pixels 240 arranged in a matrix of 3840×2160, the display apparatus 100 can achieve full color display with a resolution of ultra hi-vision (also referred to as 4K resolution, 4K2K, 4K, or the like). For example, using the pixels 240 arranged in a matrix of 7680×4320, the display apparatus 100 can achieve full color display with a resolution of super hi-vision (also referred to as 8K resolution, 8K4K, 8K, or the like). By increasing the number of pixels 240, a display apparatus 100 that can perform full-color display with 16K or 32K resolution can also be achieved.

### <Circuit Configuration Example of Pixel 230>

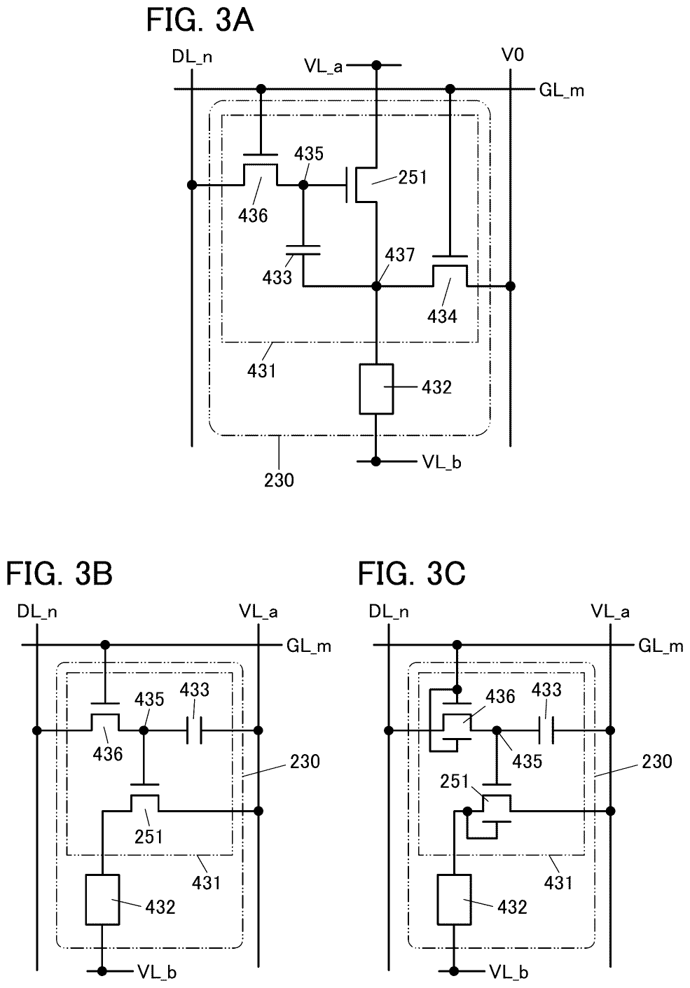

FIG. 3A is a diagram illustrating a circuit configuration example of the pixel 230. The pixel 230 includes a pixel circuit 431 and a display element 432.

Each of the wirings 236 is electrically connected to the n pixel circuits 431 in a given row among the pixel circuits 431 arranged in m rows and n columns in the display portion 104. Each of the wirings 237 is electrically connected to the m pixel circuits 431 in a given column among the pixel circuits 431 arranged in m rows and n columns.

A pixel circuit 431 includes a transistor 436, a capacitor 433, a transistor 251, and a transistor 434. The pixel circuit 431 is electrically connected to the display element 432.

One of a source electrode and a drain electrode of the transistor 436 is electrically connected to a wiring (hereinafter referred to as a signal line DL_n) supplied with a data signal (hereinafter referred to as a video signal). A gate electrode of the transistor 436 is electrically connected to a wiring supplied with a gate signal (hereinafter referred to as a scan line GL_m). The signal line DL_n and the scan line GL_m correspond to the wiring 237 and the wiring 236, respectively.

The transistor 436 has a function of controlling writing of the data signal to a node 435.

One of a pair of electrodes of the capacitor 433 is electrically connected to the node 435, and the other is electrically connected to a node 437. The other of the source electrode and the drain electrode of the transistor 436 is electrically connected to the node 435.

The capacitor 433 has a function of a storage capacitor for retaining data written to the node 435.

One of a source electrode and a drain electrode of the transistor 251 is electrically connected to a potential supply line VL_a, and the other is electrically connected to the node 437. Furthermore, a gate electrode of the transistor 251 is electrically connected to the node 435.

One of a source electrode and a drain electrode of the transistor 434 is electrically connected to a potential supply line VO, and the other is electrically connected to the node 437. Furthermore, a gate electrode of the transistor 434 is electrically connected to the scan line GL_m.

One of an anode and a cathode of the display element 432 is electrically connected to a potential supply line VL_b, and the other is electrically connected to the node 437.

As the display element 432, an organic electroluminescent element (also referred to as an organic EL element) or the like can be used, for example. However, the display element 432 is not limited thereto, and an inorganic EL element formed of an inorganic material may be used, for example. Note that an “organic EL element” and an “inorganic EL element” are collectively referred to as “EL element” in some cases.

The emission color of the EL element can be white, red, green, blue, cyan, magenta, yellow, or the like depending on materials included in the EL element.

Examples of a method for achieving color display include a method in which the display element 432 whose emission color is white is combined with a coloring layer and a method in which the display element 432 with a different emission color is provided in each pixel. The former method is more productive than the latter method. In contrast, the latter method, which requires separate formation of the display element 432 pixel by pixel, is less productive than the former method. However, the latter method can provide higher color purity of the emission color than the former method. When the display element 432 has a microcavity structure in addition to the latter method, the color purity can be further increased.

The display element 432 can adopt either a low-molecular compound or a high-molecular compound, and may include an inorganic compound. The layers included in the display element 432 can each be formed by a method such as an evaporation method (including a vacuum evaporation method), a transfer method, a printing method, an inkjet method, or a coating method.

The display element 432 may contain an inorganic compound such as quantum dots. For example, when used for the light-emitting layer, the quantum dots can function as a light-emitting material.

As a power supply potential, a potential on the relatively high potential side or a potential on the relatively low potential side can be used, for example. A power supply potential on the high potential side is referred to as a high power supply potential (also referred to as “VDD”), and a power supply potential on the low potential side is referred to as a low power supply potential (also referred to as “VSS”). A ground potential can be used as the high power supply potential or the low power supply potential. For example, in the case where a ground potential is used as the high power supply potential, the low power supply potential is a potential lower than the ground potential, and in the case where a ground potential is used as the low power supply potential, the high power supply potential is a potential higher than the ground potential.

A high power supply potential VDD is supplied to one of the potential supply line VL_a and the potential supply line VL_b, and a low power supply potential VS S is supplied to the other, for example.

In the display apparatus including the pixel circuits 431, the pixel circuits 431 are sequentially selected row by row by the circuit included in the first driver circuit 232, whereby the transistors 436 and the transistors 434 are turned on and data signals are written to the nodes 435.

When the transistor 436 and the transistor 434 are turned off, the pixel circuit 431 in which the data has been written to the node 435 is brought into a holding state. Furthermore, the amount of current flowing between the source electrode and the drain electrode of the transistor 251 is controlled in accordance with the potential of the data written to the node 435, and the display element 432 emits light with a luminance corresponding to the amount of current flow. This operation is sequentially performed row by row; thus, an image can be displayed.

FIG. 3B illustrates a variation example of a circuit configuration of the pixel 230 in FIG. 3A. The circuit configuration illustrated in FIG. 3B is a configuration excluding the transistor 434 and the potential supply line VO in the circuit configuration illustrated in FIG. 3A. For understanding of other components, description of the circuit configuration illustrated in FIG. 3A can be referred to. Therefore, the detailed description of the circuit configuration in FIG. 3B is omitted to reduce repetitive description.

Furthermore, some or all of the transistors included in the pixel circuit 431 may be transistors having a back gate. For example, the transistor 436 may be a transistor having a back gate, and the back gate and the gate thereof may be electrically connected to each other as illustrated in FIG. 3C. In addition, as in the transistor 251 illustrated in FIG. 3C, the back gate and one of the source and the drain of the transistor may be electrically connected to each other.

### [Transistor]

There is no particular limitation on the structure of the transistor included in the display apparatus of one embodiment of the present invention. For example, a planar transistor may be used, or a staggered transistor may be used. Alternatively, the transistor structure may be either a top-gate structure or a bottom-gate structure. Gate electrodes may be provided above and below a channel.

A transistor included in a peripheral driver circuit and a transistor included in a pixel circuit may have the same structure or different structures. All the transistors included in the peripheral driver circuit may have the same structure or may use the combination of two or more kinds of structures. Similarly, all the transistors included in the pixel circuit may have the same structure or may use the combination of two or more kinds of structures.

Note that when one of the gate electrodes provided above and below a channel is referred to as a “gate electrode”, the other is referred to as a “back gate electrode”. In addition, when one of the gate electrodes provided above and below a channel is referred to as a “gate”, the other is referred to as a “back gate”. Note that the gate electrode may be referred to as a “front gate electrode”. Similarly, the gate may be referred to as a “front gate”.

When the gate electrode and the back gate electrode are provided, a semiconductor layer of the transistor can be electrically surrounded by an electric field generated from the gate electrode and an electric field generated from the back gate electrode. The transistor structure in which the semiconductor layer where the channel is formed is electrically surrounded by electric fields generated from the gate electrode and the back gate electrode can be referred to as a Surrounded channel (S-channel) structure.

Thus, the back gate electrode can function in a manner similar to that of the gate electrode. The potential of the back gate electrode may be the same as the potential of the gate electrode or may be a ground potential or a given potential. In addition, when the potential of the back gate electrode is changed not in synchronization with but independently of the potential of the gate electrode, the threshold voltage of the transistor can be changed.

Providing the gate electrode and the back gate electrode and setting the potentials of the gate electrodes to be the same, a region of the semiconductor layer through which carriers flow is enlarged in the film thickness direction; thus, the amount of carrier transfer is increased. As a result, the on-state current of the transistor is increased and the field-effect mobility is increased.

Thus, the transistor can be a transistor having a high on-state current for its occupation area. That is, the occupation area of the transistor can be small for required on-state current. Accordingly, a semiconductor device having a high degree of integration can be provided.

The use of the transistor having a high on-state current for a display apparatus can reduce signal delay in wirings and can suppress a decrease in display quality even if the number of wirings is increased when the display apparatus is increased in size or resolution.

In addition, the gate electrode and the back gate electrode are formed using conductive layers and thus each have a function of preventing an electric field generated outside the transistor from affecting the semiconductor layer where the channel is formed (in particular, an electric field blocking function against static electricity and the like). Note that when the back gate electrode is formed to be larger than the semiconductor layer and the semiconductor layer is covered with the back gate electrode in the plan view, the electric field blocking function can be enhanced.

Since the gate electrode and the back gate electrode each have a function of blocking an electric field from the outside, charges of charged particles and the like generated above and below the transistor do not influence the channel formation region in the semiconductor layer. As a result, deterioration due to a stress test (e.g., an NGBT (Negative Gate Bias-Temperature) stress test where a negative voltage is applied to a gate (also referred to as “NBT” or “NBTS”)) is inhibited. In addition, the gate electrode and the back gate electrode can block an electric field generated from the drain electrode so that the electric field do not influence the semiconductor layer. Thus, a change in the rising voltage of on-state current due to a change in drain voltage can be inhibited. Note that this effect is significant when a potential is applied to each of the gate electrode and the back gate electrode.

In addition, a change in threshold voltage of a transistor including a back gate electrode between before and after a PGBT (Positive Gate Bias-Temperature) stress test where a positive voltage is applied to a gate (also referred to as “PBT” or “PBTS”) is smaller than that of a transistor including no back gate.

The BT stress test such as NGBT or PGBT is a kind of accelerated test and can evaluate, in a short time, a change by long-term use (i.e., a change over time) in characteristics of transistors. In particular, the amount of change in threshold voltage of the transistor between before and after the BT stress test is an important indicator for examination of the reliability. The smaller the amount of change in the threshold voltage between before and after the BT stress test is, the higher the reliability of the transistor becomes.

By providing the gate electrode and the back gate electrode and setting their potentials equal to each other, the amount of change in threshold voltage is reduced. Accordingly, variation in electrical characteristics among a plurality of transistors is also reduced.

In the case where light enters from the back gate electrode side, when the back gate electrode is formed using a light-blocking conductive film, the light can be prevented from entering the semiconductor layer from the back gate electrode side. Therefore, photodegradation of the semiconductor layer can be prevented, and degradation in electrical characteristics of the transistor, such as a shift in the threshold voltage, can be prevented.

### [Semiconductor Material]

There is no particular limitation on the crystallinity of a semiconductor material used for the semiconductor layer of the transistor included in the display apparatus 100. Either an amorphous semiconductor or a semiconductor having crystallinity (a microcrystalline semiconductor, a polycrystalline semiconductor, a single crystal semiconductor, or a semiconductor partly including crystal regions) may be used. The use of a semiconductor having crystallinity is preferable because degradation of the transistor characteristics can be inhibited.

For example, silicon, germanium, or the like can be used as a semiconductor material used for the semiconductor layer of the transistor. Alternatively, a compound semiconductor such as silicon carbide, gallium arsenide, a metal oxide, or a nitride semiconductor, an organic semiconductor, or the like can be used

For example, polycrystalline silicon (polysilicon), amorphous silicon, or the like can be used as a semiconductor material used for the transistor. Furthermore, an oxide semiconductor (OS), which is a kind of metal oxide, can be used as a semiconductor material used for the transistor.

As a semiconductor material used for the transistors, a metal oxide whose energy gap is greater than or equal to 2 eV, preferably greater than or equal to 2.5 eV, further preferably greater than or equal to 3 eV can be used. A typical example thereof is a metal oxide containing indium, and for example, a CAC-OS described later or the like can be used.

A transistor using a metal oxide having a wider band gap and a lower carrier density than silicon has a low off-state current; thus, charges accumulated in a capacitor that is connected in series with the transistor can be held for a long time.

The semiconductor layer can be, for example, a film represented by an In-M-Zn-based oxide that contains indium, zinc, and M (M is a metal such as aluminum, titanium, gallium, germanium, yttrium, zirconium, lanthanum, cerium, tin, neodymium, or hafnium).

In the case where the metal oxide contained in the semiconductor layer is an In-M-Zn-based oxide, it is preferable that the atomic ratio of metal elements of a sputtering target used for forming a film of the In-M-Zn oxide satisfy In M and Zn M The atomic ratio of metal elements in such a sputtering target is preferably, for example, In:M:Zn=1:1:1, In:M:Zn=1:1:1.2, In:M:Zn=3:1:2, In:M:Zn=4:2:3, In:M:Zn=4:2:4.1, In:M:Zn=5:1:6, In:M:Zn=or In:M:Zn=5:1:8. Note that the atomic ratio in the formed semiconductor layer may vary from the above atomic ratio of metal elements of the sputtering target within a range of ±40%.

A metal oxide film with low carrier density is used as the semiconductor layer. For example, for the semiconductor layer, a metal oxide whose carrier density is lower than or equal to 1×10¹⁷/cm³, preferably lower than or equal to 1×10¹⁵/cm³, further preferably lower than or equal to 1×10¹³/cm³, still further preferably lower than or equal to 1×10¹¹/cm³, even further preferably lower than 1×10¹⁰/cm³, and higher than or equal to 1×10⁻⁹/cm³ can be used. Such a metal oxide is referred to as a highly purified intrinsic or substantially highly purified intrinsic metal oxide. The metal oxide has a low density of defect states and can be regarded as a metal oxide having stable characteristics.

Note that the composition is not limited to those, and a metal oxide having an appropriate composition may be used depending on required semiconductor characteristics and electrical characteristics (field-effect mobility, threshold voltage, or the like) of the transistor. In addition, to obtain the required semiconductor characteristics of the transistor, it is preferable that the carrier density, impurity concentration, defect density, atomic ratio between a metal element and oxygen, interatomic distance, density, and the like of the metal oxide used as the semiconductor layer be set to be appropriate.

### <Metal Oxide>

Here, a metal oxide that can be used as an oxide semiconductor is described.

The metal oxide that can be used as an oxide semiconductor preferably contains at least indium or zinc. In particular, indium and zinc are preferably contained. In addition, aluminum, gallium, yttrium, tin, or the like is preferably contained. Furthermore, one or more kinds selected from boron, titanium, iron, nickel, germanium, zirconium, molybdenum, lanthanum, cerium, neodymium, hafnium, tantalum, tungsten, magnesium, cobalt, and the like may be contained.

Here, the case where the metal oxide is an In-M-Zn oxide containing indium, an element M, and zinc is considered. The element M is aluminum, gallium, yttrium, or tin. Other elements that can be used as the element M include boron, titanium, iron, nickel, germanium, zirconium, molybdenum, lanthanum, cerium, neodymium, hafnium, tantalum, tungsten, magnesium, cobalt, and the like. Note that a combination of two or more of the above elements may be used as the element M.

Note that in this specification and the like, a metal oxide containing nitrogen is also collectively referred to as a metal oxide in some cases. A metal oxide containing nitrogen may be called a metal oxynitride.

### <Classification of Crystal Structures>

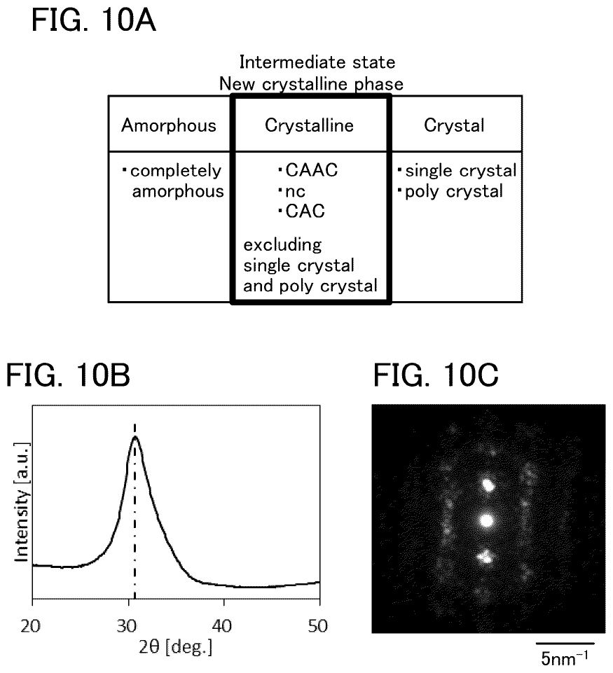

First, the classification of the crystal structures of an oxide semiconductor will be described with reference to FIG. 10A. FIG. 10A is a diagram showing the classification of crystal structures of an oxide semiconductor, typically IGZO (a metal oxide containing In, Ga, and Zn).

As shown in FIG. 10A, an oxide semiconductor is roughly classified into “Amorphous”, “Crystalline”, and “Crystal”. The term “Amorphous” includes completely amorphous. The term “Crystalline” includes CAAC (c-axis-aligned crystalline), nc (nanocrystalline), and CAC (cloud-aligned composite) (excluding single crystal and poly crystal). Note that the term “Crystalline” excludes single crystal, poly crystal, and completely amorphous. Moreover, the term “Crystal” includes single crystal and poly crystal.

Note that the structures in the thick frame in FIG. 10A are in an intermediate state between “Amorphous” and “Crystal”, and belong to a new crystalline phase. That is, these structures are completely different from “Amorphous”, which is energetically unstable, and “Crystal”.

A crystal structure of a film or a substrate can be evaluated with an X-ray diffraction (XRD) spectrum. FIG. 10B shows an XRD spectrum, which is obtained by GIXD (Grazing-Incidence XRD) measurement, of a CAAC-IGZO film classified into “Crystalline”. Note that a GIXD method is also referred to as a thin film method or a Seemann-Bohlin method. The XRD spectrum that is shown in FIG. 10B and obtained by GIXD measurement may be hereinafter simply referred to as an XRD spectrum in this specification. The CAAC-IGZO film in FIG. 10B has a composition in the neighborhood of In:Ga:Zn=4:2:3 [atomic ratio]. The CAAC-IGZO film in FIG. 10B has a thickness of 500 nm.

In FIG. 10B, the horizontal axis represents 2θ [deg.], and the vertical axis represents Intensity [a.u.]. As shown in FIG. 10B, a clear peak indicating crystallinity is detected in the XRD spectrum of the CAAC-IGZO film. Specifically, a peak indicating c-axis alignment is detected at 2θ of around 31° in the XRD spectrum of the CAAC-IGZO film. As shown in FIG. the peak at 2θ of around 31° is asymmetric with respect to the axis of the angle at which the peak intensity is detected.

A crystal structure of a film or a substrate can also be evaluated with a diffraction pattern obtained by a nanobeam electron diffraction (NBED) method (such a pattern is also referred to as a nanobeam electron diffraction pattern). FIG. 10C shows a diffraction pattern of the CAAC-IGZO film. FIG. 10C shows a diffraction pattern obtained by NBED in which an electron beam is incident in the direction parallel to the substrate. The CAAC-IGZO film in FIG. 10C has a composition in the neighborhood of In:Ga:Zn=4:2:3 [atomic ratio]. In the nanobeam electron diffraction method, electron diffraction is performed with a probe diameter of 1 nm.

As shown in FIG. 10C, a plurality of spots indicating c-axis alignment are observed in the diffraction pattern of the CAAC-IGZO film.

### <Structure of Oxide Semiconductor>

Oxide semiconductors may be classified in a manner different from that in FIG. 10A when classified in terms of the crystal structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the CAAC-OS, the nc-OS, and the a-like OS will be described in detail.

### [CAAC-OS]

The CAAC-OS is an oxide semiconductor that has a plurality of crystal regions each of which has c-axis alignment in a particular direction. Note that the particular direction refers to the film thickness direction of a CAAC-OS film, the normal direction of the surface where the CAAC-OS film is formed, or the normal direction of the surface of the CAAC-OS film. The crystal region refers to a region having a periodic atomic arrangement. Note that when an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that the distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more minute crystals (crystals each of which has a maximum diameter of less than 10 nm). In the case where the crystal region is formed of one minute crystal, the maximum diameter of the crystal region is less than 10 nm. In the case where the crystal region is formed of a large number of minute crystals, the size of the crystal region may be approximately several tens of nanometers.

In an In-M-Zn oxide (the element M is one or more kinds selected from aluminum, gallium, yttrium, and tin), the CAAC-OS tends to have a layered crystal structure (also referred to as a layered structure) in which a layer containing indium (In) and oxygen (hereinafter, an In layer) and a layer containing the element M, zinc (Zn), and oxygen (hereinafter, an (M,Zn) layer) are stacked. Indium and the element M can be replaced with each other. Therefore, indium may be contained in the (M,Zn) layer. In addition, the element M may be contained in the In layer. Note that Zn may be contained in the In layer. Such a layered structure is observed as a lattice image in a high-resolution TEM image, for example.

When the CAAC-OS film is subjected to structural analysis by out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear grain boundary cannot be observed even in the vicinity of the distortion in the CAAC-OS. That is, formation of a grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

A crystal structure in which a clear grain boundary is observed is what is called polycrystal. It is highly probable that the crystal grain boundary becomes a recombination center and traps carriers and thus decreases the on-state current and field-effect mobility of a transistor, for example. Thus, the CAAC-OS in which no clear grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a grain boundary as compared with an In oxide.

The CAAC-OS is an oxide semiconductor with high crystallinity in which no clear grain boundary is observed. Thus, in the CAAC-OS, a reduction in electron mobility due to the grain boundary is less likely to occur. Moreover, since the crystallinity of an oxide semiconductor might be decreased by entry of impurities, formation of defects, or the like, the CAAC-OS can be regarded as an oxide semiconductor that has small amounts of impurities and defects (e.g., oxygen vacancies). Thus, an oxide semiconductor including the CAAC-OS is physically stable. Therefore, the oxide semiconductor including the CAAC-OS is resistant to heat and has high reliability. In addition, the CAAC-OS is stable with respect to high temperature in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a minute crystal. Note that the size of the minute crystal is, for example, greater than or equal to 1 nm and less than or equal to 10 nm, particularly greater than or equal to 1 nm and less than or equal to 3 nm; thus, the minute crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis using out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or smaller than the diameter of a nanocrystal (e.g., larger than or equal to 1 nm and smaller than or equal to 30 nm).

### [A-Like OS]

The a-like OS is an oxide semiconductor having a structure between those of the nc-OS and the amorphous oxide semiconductor. The a-like OS includes a void or a low-density region. That is, the a-like OS has lower crystallinity than the nc-OS and the CAAC-OS. Moreover, the a-like OS has higher hydrogen concentration in the film than the nc-OS and the CAAC-OS.

### <Structure of Oxide Semiconductor>

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Note that the atomic ratios of In, Ga, and Zn to the metal elements contained in the CAC-OS in an In—Ga—Zn oxide are denoted with [In], [Ga], and [Zn], respectively. For example, the first region in the CAC-OS in the In—Ga—Zn oxide has [In] higher than [In] in the composition of the CAC-OS film. Moreover, the second region has [Ga] higher than [Ga] in the composition of the CAC-OS film. Alternatively, for example, the first region has [In] higher than [In] in the second region and [Ga] lower than [Ga] in the second region. Moreover, the second region has [Ga] higher than [Ga] in the first region and [In] lower than [In] in the first region.

Specifically, the first region includes indium oxide, indium zinc oxide, or the like as its main component. The second region includes gallium oxide, gallium zinc oxide, or the like as its main component. That is, the first region can be referred to as a region containing In as its main component. The second region can be referred to as a region containing Ga as its main component.

Note that a clear boundary between the first region and the second region cannot be observed in some cases.

For example, energy dispersive X-ray spectroscopy (EDX) is used to obtain EDX mapping, and according to the EDX mapping, the CAC-OS in the In—Ga—Zn oxide can be found to have a structure in which the region containing In as its main component (the first region) and the region containing Ga as its main component (the second region) are unevenly distributed and mixed.

In the case where the CAC-OS is used for a transistor, a switching function (on/off switching function) can be given to the CAC-OS owing to the complementary action of the conductivity derived from the first region and the insulating property derived from the second region. That is, the CAC-OS has a conducting function in part of the material and has an insulating function in another part of the material; as a whole, the CAC-OS has a function of a semiconductor. Separation of the conducting function and the insulating function can maximize each function. Accordingly, when a CAC-OS is used for a transistor, a high on-state current (Ion), a high field-effect mobility (μ), and favorable switching operation can be achieved.

An oxide semiconductor has various structures with different properties. Two or more kinds among an amorphous oxide semiconductor, a polycrystalline oxide semiconductor, an a-like OS, a CAC-OS, an nc-OS, and a CAAC-OS may be included in an oxide semiconductor of one embodiment of the present invention.

### <Transistor Including Oxide Semiconductor>

Next, the case where the above oxide semiconductor is used for a transistor is described.

When the above oxide semiconductor is used for a transistor, a transistor with high field-effect mobility can be achieved. In addition, a transistor having high reliability can be achieved.

An oxide semiconductor having a low carrier concentration is preferably used for a channel formation region of the transistor. For example, the carrier concentration in an oxide semiconductor in the channel formation region is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Electric charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon.

### <Impurity>

Here, the influence of each impurity in the oxide semiconductor is described.

When silicon or carbon, which is one of Group 14 elements, is contained in the oxide semiconductor, defect states are formed in the oxide semiconductor. Thus, the concentration of silicon or carbon in the channel formation region of the oxide semiconductor and the concentration of silicon or carbon in the vicinity of an interface with the channel formation region of the oxide semiconductor (the concentrations obtained by secondary ion mass spectrometry (SIMS)) are each set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the channel formation region of the oxide semiconductor that is obtained by SIMS is set lower than or equal to 1×10¹⁸ atoms/cm³, preferably lower than or equal to 2×10¹⁶ atoms/cm³.

When the oxide semiconductor contains nitrogen, the oxide semiconductor easily becomes n-type because of generation of electrons serving as carriers and an increase in carrier concentration. As a result, a transistor using an oxide semiconductor containing nitrogen as a semiconductor is likely to have normally-on characteristics. When nitrogen is contained in the oxide semiconductor, a trap state is sometimes formed. This might make the electrical characteristics of the transistor unstable. Therefore, the concentration of nitrogen in the channel formation region of the oxide semiconductor that is obtained by SIMS is set lower than 5×10¹⁹ atoms/cm³, preferably set lower than or equal to 5×10¹⁸ atoms/cm³, further preferably lower than or equal to 1×10¹⁸ atoms/cm³, and still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor containing hydrogen is likely to have normally-on characteristics. For this reason, hydrogen in the channel formation region of the oxide semiconductor is preferably reduced as much as possible. Specifically, the hydrogen concentration in the channel formation region of the oxide semiconductor that is obtained by SIMS is set lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, and yet still further preferably lower than 1×10¹⁸ atoms/cm³.

When an oxide semiconductor with sufficiently reduced impurities is used for a channel formation region of a transistor, stable electrical characteristics can be given.

### <Other Semiconductor Materials>

A semiconductor material that can be used for a semiconductor layer of a transistor is not limited to the above metal oxides. A semiconductor material that has a band gap (a semiconductor material that is not a zero-gap semiconductor) may be used for the semiconductor layer. For example, a single element semiconductor such as silicon, a compound semiconductor such as gallium arsenide, or a layered material functioning as a semiconductor (also referred to as an atomic layer material or a two-dimensional material) is preferably used as a semiconductor material. In particular, a layered material functioning as a semiconductor is preferably used as a semiconductor material.

Here, in this specification and the like, the layered material generally refers to a group of materials having a layered crystal structure. In the layered crystal structure, layers formed by covalent bonding or ionic bonding are stacked with bonding such as the Van der Waals force, which is weaker than covalent bonding or ionic bonding. The layered material has high electrical conductivity in a monolayer, that is, high two-dimensional electrical conductivity. When a material functioning as a semiconductor and having high two-dimensional electrical conductivity is used for a channel formation region, a transistor having a high on-state current can be provided.

Examples of the layered material include graphene, silicene, and chalcogenide. Chalcogenide is a compound containing chalcogen. Chalcogen is a general term of elements belonging to Group 16, which includes oxygen, sulfur, selenium, tellurium, polonium, and livermorium. Examples of chalcogenide include transition metal chalcogenide and chalcogenide of Group 13 elements.

For a semiconductor layer of a transistor, a transition metal chalcogenide functioning as a semiconductor is preferably used, for example. Specific examples of the transition metal chalcogenide which can be used for the semiconductor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

The driver circuit 102 has a function of generating a signal for controlling the display portion 104 with a control signal and an image signal supplied from the input-output terminal portion 106 and supplying the signal to the display portion 104. Higher resolution of the display portion requires high-speed operation of the driver circuit 102. Thus, the driver circuit 102 are preferably configured with transistors with high operation speed. For example, the driver circuit 102 is preferably formed using a crystalline semiconductor.

Transistors included in the display portion 104 are preferably transistors (OS transistors) including an oxide semiconductor in a semiconductor layer where a channel is formed. The oxide semiconductor has an energy gap of 2 eV or higher and thus can reduce off-state current of transistors. That is, OS transistors are preferably used as the transistor 436 and/or the transistor 434.

Moreover, the OS transistor has a high breakdown voltage between its source and drain. For example, since the transistor 251 functions as a switch for supplying power to the display element 432, a transistor having a high breakdown voltage between its source and drain is suitable for the transistor 251. Thus, it is preferable to use an OS transistor as the transistor 251.

When a semiconductor material used for the transistors included in the driver circuit 102 is made different from a semiconductor material used for the transistors included in the display portion 104 depending on the purpose and/or usage, higher reliability and lower power consumption of the display apparatus 100 can be achieved.

Alternatively, the semiconductor material used for the transistors included in the driver circuit 102 and the semiconductor material used for the transistors included in the display portion 104 may be the same, depending on the purpose and/or the usage.

For example, the display apparatus 100 may have a stacked-layer structure of the driver circuit 102 formed using a single crystal silicon substrate and the display portion 104 formed using a single crystal silicon substrate.

By providing the display portion 104 to overlap with the driver circuit 102, the size of the display apparatus 100 can be reduced. In the case where the external dimension of the display apparatus 100 is constant, the area of the display portion 104 can be increased. Accordingly, the resolution of the display apparatus 100 can be increased. In addition, in the case where the pixel resolution is constant, the occupation area per pixel can be increased. Accordingly, the emission luminance of the display apparatus can be improved. In addition, the pixel aperture ratio can be increased. For example, the pixel aperture ratio can be greater than or equal to 40% and less than 100%, preferably greater than or equal to 50% and less than or equal to 95%, and further preferably greater than or equal to 60% and less than or equal to 95%. Moreover, an increase of the occupation area per pixel can reduce the density of current supplied to a pixel. Accordingly, the load applied to the pixel is reduced, so that the reliability of the display apparatus 100 can be increased.

The display apparatus 100 of one embodiment of the present invention can be suitably used in VR equipment such as head-mounted displays, glasses-type AR equipment, or the like. The display apparatus 100 of one embodiment of the present invention can achieve higher aperture ratio and has favorable visibility. Thus, VR equipment, AR equipment, or the like using the display apparatus 100 of one embodiment of the present invention provides high immersion feelings. Moreover, the display apparatus 100 of one embodiment of the present invention can be suitably used in electronic devices having relatively small display portions, without being limited to the above equipment. For example, the display apparatus 100 can be suitably used in a display portion of a wearable electronic device, such as a wrist watch.

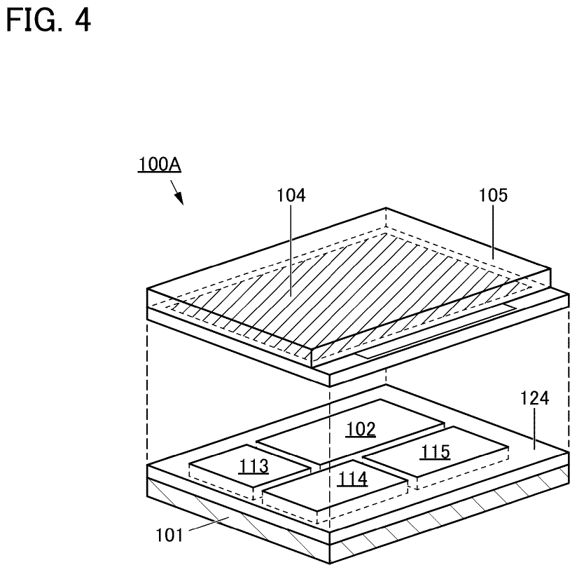

The semiconductor device that can be provided over the substrate 101 is not limited to the driver circuit 102. A memory device 113, a GPU 114, a CPU 115, and/or the like may be provided over the substrate 101. A display apparatus 100A illustrated in FIG. 4 includes the driver circuit 102, the memory device 113, the GPU 114, and the CPU 115 over the substrate 101. Note that in FIG. 4, the semiconductor device and the display portion 104 over the substrate 101 are separately displayed for easy understanding of the structure of the present invention. In FIG. 4, illustrations of the wiring group 103 and the like are omitted.

Note that the input-output terminal portion 106 may be provided for a bottom surface of the substrate 101 by a TSV (Through Silicon Via) technique or the like, instead of the display portion 104 side.

### <Example of Manufacturing Method>

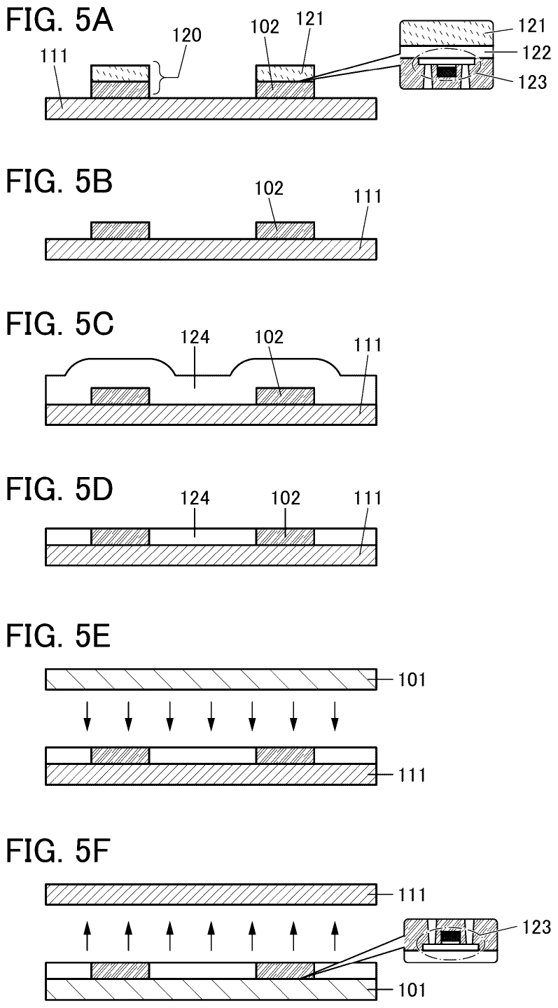

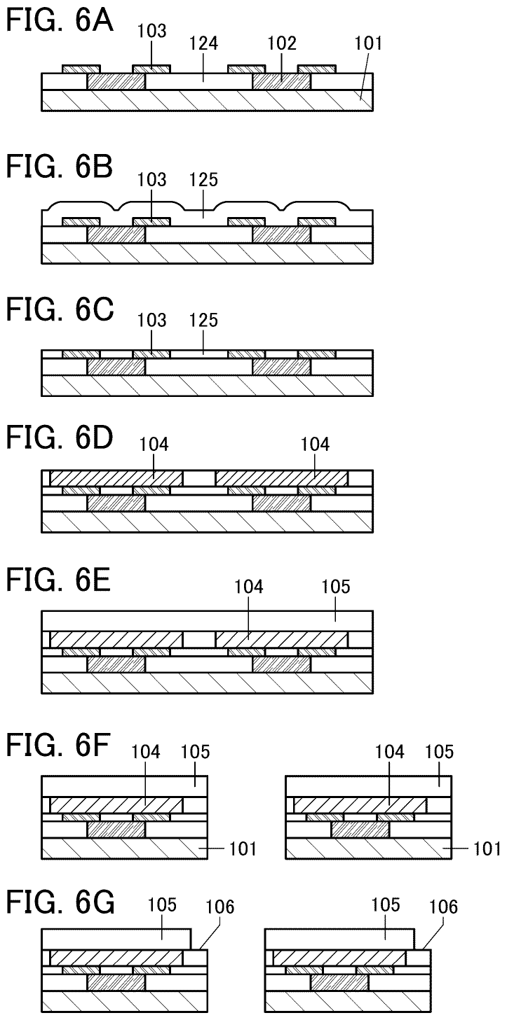

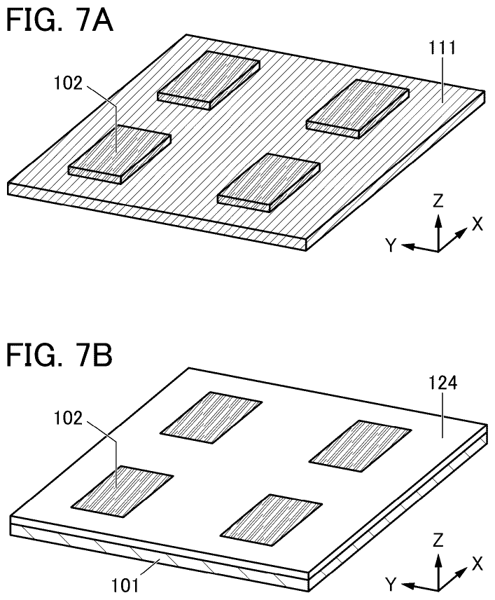

An example of a method for manufacturing the display apparatus 100 will be described with reference to drawings. FIG. 5 and FIG. 6 are cross-sectional views illustrating a method for manufacturing the display apparatus 100. FIG. 7 to FIG. 9 are perspective views for illustrating the method for manufacturing the display apparatus 100. In this embodiment, a method for manufacturing a plurality of display apparatuses 100 all at once will be described.

### [Step 1]

A semiconductor chip 120 is provided over a support substrate 111 (see FIG. 5A). The semiconductor chip 120 is the driver circuit 102 provided in an SOI (Silicon on Insulator) substrate and the driver circuit 102 including a transistor 123 is formed over a Si substrate 121 with a BOX (Buried Oxide) layer 122 therebetween. In this step, the semiconductor chip 120 is placed such that the driver circuit 102 side thereof faces the support substrate 111. In the case where the transistor 123 is a top-gate transistor, the semiconductor chip 120 is placed such that a gate electrode of the transistor 123 is placed closer to the support substrate 111 than the semiconductor layer is.

### [Step 2]

Next, polishing treatment is performed and the Si substrate 121 is removed (see FIG. 5B and FIG. 7A). The removal of the Si substrate 121 may be performed until the BOX layer 122 is exposed.

### [Step 3]

Next, an insulating layer 124 is formed to cover the driver circuit 102 (see FIG. 5C).

### [Step 4]

Next, planarization treatment is performed on the insulating layer 124 (see FIG. 5D). As the planarization treatment, a known method such as chenical mechanical polishing (CMP) treatment can be employed. The planarization treatment makes the top surface of the insulating layer 124 substantially level with an exposed surface of the driver circuit 102.

### [Step 5]

Next, the substrate 101 is attached onto the insulating layer 124 and the driver circuit 102 (see FIG. 5E). An insulating layer containing the same constituent element as the insulating layer 124 may be provided for the attachment surface of the substrate 101. Providing the insulating layer enables the both to be attached to each other more easily. For example, in the case where the insulating layer 124 is silicon oxide, silicon oxide may be provided for the attachment surface of the substrate 101.

### [Step 6]

Next, the support substrate 111 is removed, and the substrate 101 is placed on the lower side (see FIG. 5F and FIG. 7B). The driver circuit 102 including the transistor 123 is placed such that the semiconductor layer of the transistor 123 is closer to the substrate 101 than the gate electrode thereof is.

Polishing treatment may be employed for the removal of the support substrate 111. Note that a separation layer may be provided between the support substrate 111 and the driver circuit 102 in advance, and the support substrate 111 may be removed by separation treatment.

### [Step 7]

Next, the wiring group 103 is formed over the insulating layer 124 and the driver circuit 102 (see FIG. 6A). The wiring group 103 can be formed with an appropriate combination of any of various deposition methods, a photolithography method, an etching method, and the like. The wiring group 103 includes a plurality of wirings. At least some of the wirings included in the wiring group 103 are electrically connected to at least some of the transistors included in the driver circuit 102.

### [Step 8]

Next, an insulating layer 125 is formed to cover the wiring group 103 (see FIG. 6B).

### [Step 9]

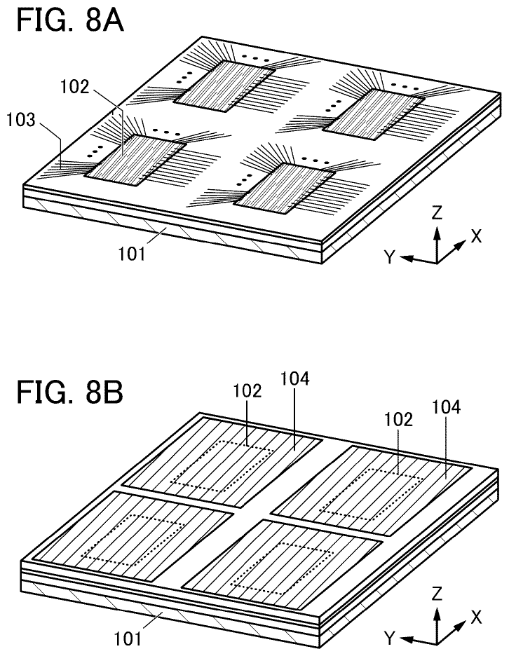

Next, planarization treatment is performed on the insulating layer 125 (see FIG. 6C and FIG. 8A). The planarization treatment may be performed by a known method such as CMP treatment. The planarization treatment makes the top surface of the insulating layer 125 substantially level with an exposed surface of the wiring group 103.

### [Step 10]

Next, the display portion 104 is formed over the insulating layer 125 and the wiring group 103 (see FIG. 6D and FIG. 8B). The display portion 104 can be formed with an appropriate combination of any of various deposition methods, a photolithography method, an etching method, and the like. In this embodiment, the top-emission display portion 104 including an organic EL element is formed.

### [Step 11]

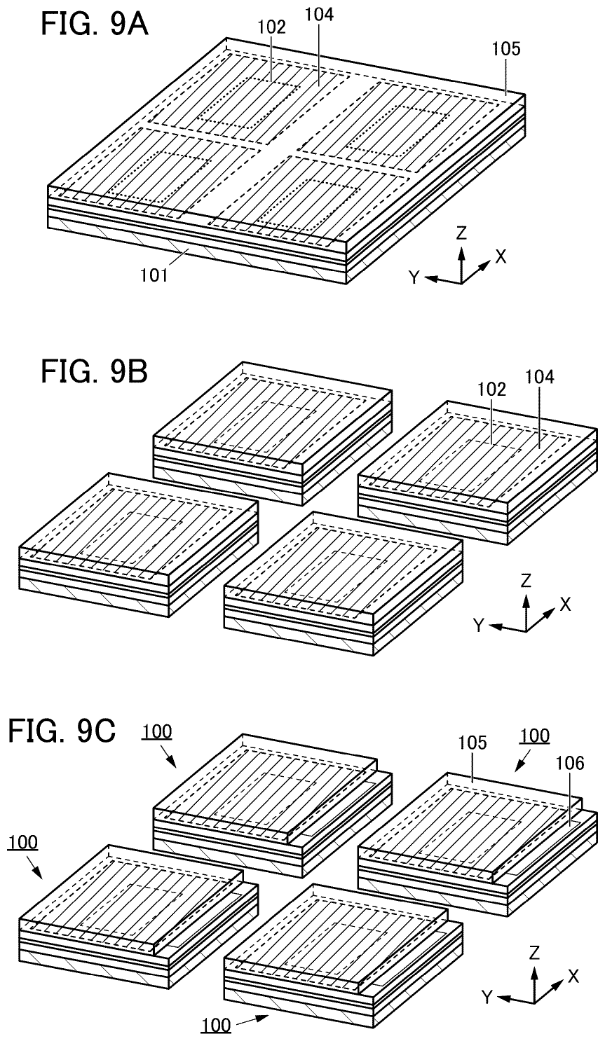

Next, a substrate 105 is formed over the display portion 104. Note that the substrate 105 may be provided with a color filter, a microlens lens, and/or the like (see FIG. 6E and FIG. 9A). A sealant may be provided between the display portion 104 and the substrate 105. The sealant may be provided along the perimeter portion of the region where the display portion 104 overlaps with the substrate 105, or the sealant may be entirely provided in the region where the display portion 104 and the substrate 105 overlap with each other.

### [Step 12]

Next, the structure manufactured through steps up to Step 11 is separated by the display portion 104 (see FIG. 6F and FIG. 9B).

### [Step 13]

Next, a part of the substrate 105 is removed to expose the input-output terminal portion 106 (see FIG. 6G and FIG. 9C). In this manner, the display apparatus 100 can be manufactured.

### [Substrate]

There are no considerable limitations on materials used for the substrate 101, the substrate 105, and the support substrate 111. The material is determined by the purpose in consideration of whether it has a light-transmitting property, heat resistance high enough to withstand heat treatment, and the like. For example, a glass substrate of barium borosilicate glass, aluminosilicate glass, or the like; a ceramics substrate; a quartz substrate; a sapphire substrate; or the like can be used. Alternatively, a semiconductor substrate, a flexible substrate, an attachment film, a base film, or the like may be used.

Examples of the semiconductor substrate include a semiconductor substrate using silicon, germanium, or the like as a material and a compound semiconductor substrate using silicon carbide, silicon germanium, gallium arsenide, indium phosphide, zinc oxide, or gallium oxide as a material. For the semiconductor substrate, a single-crystal semiconductor or a polycrystalline semiconductor may be used.

Note that a light-transmitting substrate is used as the substrate 105 in this embodiment. For the substrate 101 and the substrate 105, materials having close thermal expansion coefficients are preferably used. Thus, the same material is preferably used for the substrate 101 and the substrate 105.

In order to increase the flexibility of the display apparatus 100, a flexible substrate, an attachment film, a base film, or the like may be used as the substrate 101 and the substrate 105.

As the materials of the flexible substrate, the attachment film, the base film, and the like, for example, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyethersulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, cellulose nanofiber, or the like can be used.

When the above-described material is used for the substrate, a lightweight display apparatus can be provided. Furthermore, when the above-described material is used for the substrate, a shock-resistant display apparatus can be provided. Moreover, when the above-described material is used for the substrate, a display apparatus that is less likely to be broken can be provided.

The flexible substrate used as the substrate 101 and the substrate 105 preferably has a lower coefficient of linear expansion because deformation due to an environment is inhibited. For the flexible substrate used as the substrate 101 and the substrate 105, for example, a material whose coefficient of linear expansion is lower than or equal to 1×10⁻³/K, lower than or equal to 5×10⁻⁵/K, or lower than or equal to 1×10⁻⁵/K may be used. In particular, aramid is suitable for the flexible substrate because of its low coefficient of linear expansion.

### [Conductive Layer]

As a conductive material that can be used for the gate, the source, and the drain of the transistor and conductive layers such as various wirings and electrodes included in the display apparatus, a metal element selected from aluminum, chromium, copper, silver, gold, platinum, tantalum, nickel, titanium, molybdenum, tungsten, hafnium (Hf), vanadium (V), niobium (Nb), manganese, magnesium, zirconium, beryllium, and the like; an alloy containing the above metal element as a component; an alloy containing the above metal elements in combination; or the like can be used. Alternatively, a semiconductor typified by polycrystalline silicon containing an impurity element such as phosphorus, or silicide such as nickel silicide may be used. There is no particular limitation on the formation method of the conductive material, and a variety of formation methods such as an evaporation method, a CVD method, a sputtering method, and a spin coating method can be employed.

As the conductive material that can be used for the conductive layer, a conductive material containing oxygen, such as an indium tin oxide, an indium oxide containing tungsten oxide, an indium zinc oxide containing tungsten oxide, an indium oxide containing titanium oxide, an indium tin oxide containing titanium oxide, an indium zinc oxide, or an indium tin oxide to which silicon oxide is added, can be used. Moreover, a conductive material containing nitrogen, such as titanium nitride, tantalum nitride, or tungsten nitride, can be used. In addition, a stacked-layer structure in which a conductive material containing oxygen, a conductive material containing nitrogen, and a material containing the above-described metal element are combined as appropriate can be used.

The conductive material that can be used for the conductive layer may have a single-layer structure or a stacked-layer structure of two or more layers. For example, the conductive layer may have a single layer structure of an aluminum layer containing silicon, a two-layer structure in which a titanium layer is stacked over an aluminum layer, a two-layer structure in which a titanium layer is stacked over a titanium nitride layer, a two-layer structure in which a tungsten layer is stacked over a titanium nitride layer, a two-layer structure in which a tungsten layer is stacked over a tantalum nitride layer, or a three-layer structure including a titanium layer, an aluminum layer stacked over the titanium layer, and a titanium layer formed thereover. Alternatively, an aluminum alloy containing one or more elements selected from titanium, tantalum, tungsten, molybdenum, chromium, neodymium, and scandium may be used as the conductive material.

### [Insulating Layer]

For each of the insulating layers, a single layer or a stack layer of materials selected from aluminum nitride, aluminum oxide, aluminum nitride oxide, aluminum oxynitride, magnesium oxide, silicon nitride, silicon oxide, silicon nitride oxide, silicon oxynitride, gallium oxide, germanium oxide, yttrium oxide, zirconium oxide, lanthanum oxide, neodymium oxide, hafnium oxide, tantalum oxide, aluminum silicate, and the like. A material in which a plurality of materials selected from an oxide material, a nitride material, an oxynitride material, and a nitride oxide material are mixed may be used.

Note that in this specification, a nitride oxide refers to a compound that contains more nitrogen than oxygen. An oxynitride refers to a compound that contains more oxygen than nitrogen. The content of each element can be measured by Rutherford backscattering spectrometry (RBS), for example.

In particular, in the case of using an OS transistor, an insulating layer(s) of an insulating material through which impurities do not easily pass is preferably formed so that the OS transistor can be covered with the insulating layer or placed between such insulating layers. For example, a single layer or a stacked layer of an insulating material containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum may be used. Examples of the insulating material through which impurities are less likely to pass include aluminum oxide, aluminum nitride, aluminum oxynitride, aluminum nitride oxide, gallium oxide, germanium oxide, yttrium oxide, zirconium oxide, lanthanum oxide, neodymium oxide, hafnium oxide, tantalum oxide, and silicon nitride.

The insulating layer that can function as a planarization layer can be formed using an organic material having heat resistance, such as polyimide, an acrylic resin, a benzocyclobutene-based resin, polyamide, or an epoxy resin. Other than the above organic materials, it is also possible to use a low dielectric constant material (a low-k material), a siloxane-based resin, PSG (phosphosilicate glass), BPSG (borophosphosilicate glass), or the like. Note that a plurality of insulating layers formed of these materials may be stacked.

Note that the siloxane-based resin corresponds to a resin including a Si—O—Si bond formed using a siloxane-based material as a starting material. In the siloxane-based resin, an organic group (e.g., an alkyl group or an aryl group), a fluoro group, or the like may be used as a substituent. In addition, the organic group may include a fluoro group.

A surface of the insulating layer or the like may be subjected to CMP treatment. By the CMP treatment, unevenness of a surface can be reduced, and coverage with an insulating layer and a conductive layer that are formed later can be increased.

Note that the insulating layers, the semiconductor layer, the conductive layers used for forming electrodes and wirings, and the like included in the display apparatus can be formed by a sputtering method, a chemical vapor deposition (CVD) method, a vacuum evaporation method, a pulsed laser deposition (PLD) method, an atomic layer deposition (ALD) method, a plasma ALD (PEALD) method, or the like. As the CVD method, a plasma-enhanced chemical vapor deposition (PECVD) method or a thermal CVD method may be used. As the thermal CVD method, for example, a metal organic chemical vapor deposition (MOCVD: Metal Organic CVD) method may be used.

Alternatively, the insulating layers, the semiconductor layer, the conductive layers used for forming electrodes and wirings, and the like included in the display apparatus may be formed by a method such as spin coating, dipping, spray coating, ink-jetting, dispensing, screen printing, offset printing, slit coating, roll coating, curtain coating, and knife coating.

A PECVD method can provide a high-quality film at a relatively low temperature. With use of a deposition method that does not use plasma at the time of deposition, such as an MOCVD method, an ALD method, or a thermal CVD method, damage is not easily caused on a surface where the film is formed. For example, a wiring, an electrode, an element (a transistor, a capacitor, or the like), or the like included in a semiconductor device might be charged up by receiving charge from plasma. In this case, accumulated charge might break the wiring, the electrode, the element, or the like included in the semiconductor device. By contrast, in the case of a deposition method not using plasma, such plasma damage is not caused; thus, the yield of semiconductor devices can be increased. Moreover, since plasma damage during deposition is not caused, a film with few defects can be obtained.

Unlike a deposition method in which particles ejected from a target or the like are deposited, a CVD method and an ALD method are deposition methods in which a film is formed by reaction at a surface of an object to be processed. Thus, the CVD method and the ALD method are deposition methods that can provide good step coverage almost regardless of the shape of an object to be processed. In particular, the ALD method enables excellent step coverage and excellent thickness uniformity and thus is suitably used to cover a surface of an opening portion with a high aspect ratio, for example. Meanwhile, the ALD method has a comparatively low deposition rate, and thus is preferably used in combination with another deposition method with a high deposition rate, such as the CVD method, in some cases.

When a CVD method or an ALD method is used, the composition of a film to be obtained can be controlled with the flow rate ratio of source gases. For example, by the CVD method and the ALD method, a film with a certain composition can be formed depending on the flow rate ratio of the source gases. Moreover, for example, by the CVD method and the ALD method, a film whose composition is continuously changed can be formed by changing the flow rate ratio of the source gases during deposition. In the case of forming a film while changing the flow rate ratio of the source gases, as compared with the case of forming a film with use of a plurality of deposition chambers, the time taken for the deposition can be shortened because the time taken for transfer and pressure adjustment is omitted. Thus, the productivity of the semiconductor device can be increased in some cases.

Note that in the case of forming a film by an ALD method, a gas that does not contain chlorine is preferably used as a material gas.

Furthermore, in the case where an oxide semiconductor is formed by a sputtering method, a chamber of a sputtering apparatus is preferably evacuated to a high vacuum (to the degree of approximately 5×10⁻⁷ Pa to 1×10⁻⁴ Pa, for example) by an adsorption vacuum evacuation pump such as a cryopump so that water and the like acting as impurities for the oxide semiconductor film are removed as much as possible. In particular, the partial pressure of gas molecules corresponding to H₂O (gas molecules corresponding to m/z=18) in the chamber in the standby mode of the sputtering apparatus is preferably lower than or equal to 1×10⁻⁴ Pa, further preferably lower than or equal to 5×10⁻⁵ Pa. The deposition temperature is preferably higher than or equal to RT and lower than or equal to 500° C., further preferably higher than or equal to RT and lower than or equal to 300° C., still further preferably higher than or equal to RT and lower than or equal to 200° C.

In addition, increasing the purity of a sputtering gas is necessary. For example, as an oxygen gas or an argon gas used for a sputtering gas, a gas which is highly purified to have a dew point of −40° C. or lower, preferably −80° C. or lower, further preferably −100° C. or lower, and still further preferably −120° C. or lower is used, whereby entry of moisture or the like into the oxide semiconductor film can be minimized as much as possible.

In the case where the insulating layer, the conductive layer, the semiconductor layer, or the like is formed by a sputtering method using a sputtering gas containing oxygen, oxygen can be supplied to a layer over which the layer is formed. As the amount of oxygen contained in the sputtering gas increases, the amount of oxygen supplied to the layer over which the layer is formed tends to increase.

When such a layer (thin film) included in the display apparatus is processed, a photolithography method or the like can be used for the processing. Alternatively, an island-shaped layer may be formed by a deposition method using a blocking mask. Alternatively, a nanoimprinting method, a sandblasting method, a lift-off method, or the like may be used for the processing of the layer. As a photolithography method, a method in which a resist mask is formed over a layer (thin film) to be processed, part of the layer (thin film) is selected and removed by using the resist mask as a mask, and the resist mask is removed, and a method in which a photosensitive layer is formed, and then the layer is exposed to light and developed to be processed into a desired shape are given.

In the case of using light in the photolithography method, an i-line (a wavelength of 365 nm), a g-line (a wavelength of 436 nm), and an h-line (a wavelength of 405 nm), or combined light of them can be used for light exposure. Besides, ultraviolet light, KrF laser light, ArF laser light, or the like can also be used. Exposure may be performed by liquid immersion exposure technique. Furthermore, as the light used for the exposure, extreme ultra-violet (EUV) light, X-rays, or the like may be used. Furthermore, instead of the light used for the exposure, an electron beam can also be used. It is preferable to use extreme ultraviolet light, X-rays, or an electron beam because extremely minute processing can be performed. Note that in the case of performing exposure by scanning of a beam such as an electron beam, a photomask is not needed.

For removal (etching) of the layer (thin film), a dry etching method, a wet etching method, or the like can be used. Alternatively, the etching methods may be used in combination.

### Variation Example

The semiconductor chip 120 may be provided over the substrate 101 without using the support substrate 111. Specifically, the driver circuit 102 side of the semiconductor chip 120 is placed so as to face the substrate 101. After that, the Si substrate 121 is removed, the insulating layer 124 is provided, planarization treatment is performed so that the top surface of the insulating layer 124 is substantially level with the exposed surface of the driver circuit 102. The subsequent steps may be performed in a manner similar to Step 7 and the following steps.

### [Structure Example of Display Module]

Next, a structure example of a display module including the display apparatus of one embodiment of the present invention will be described below.

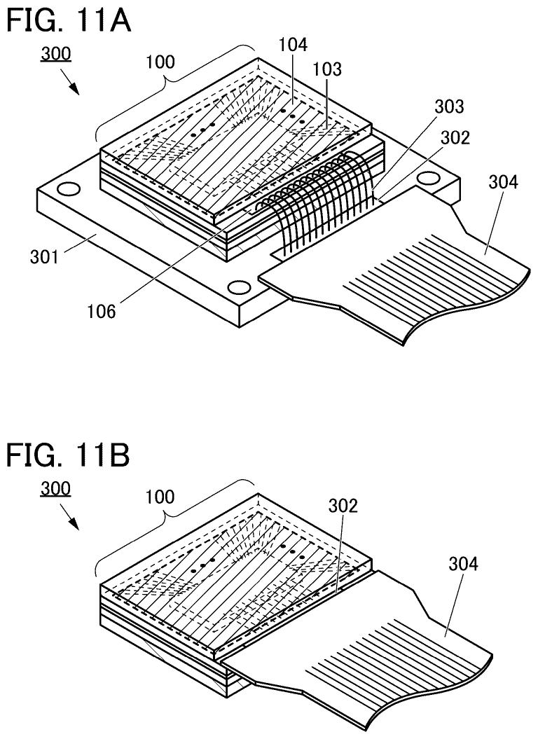

FIG. 11A and FIG. 11B are schematic perspective views of a display module 300. The display module 300 illustrated in FIG. 11A includes the display apparatus 100 over a printed wiring board 301. The printed wiring board 301 includes wirings inside a substrate formed of an insulator and/or on the surface of the substrate.

In the display module 300 illustrated in FIG. 11A, the input-output terminal portion 106 of the display apparatus 100 is electrically connected to a terminal portion 302 of the printed wiring board 301 through a wire 303. The wire 303 can be formed in wire bonding. After the wire 303 is formed, the wire 303 may be covered with a resin material or the like. Note that the display apparatus 100 and the printed wiring board 301 may be electrically connected to each other by a method other than the wire bonding.

The display module 300 in FIG. 11A is electrically connected to a FPC 304 (Flexible printed circuits). The FPC 304 has a structure in which a film formed of an insulator is provided with a wiring. The FPC 304 is flexible. The FPC 304 functions as a wiring for supplying a video signal, a power supply potential, and/or the like to the display apparatus 100 from the outside. In addition, an IC may be mounted on the FPC 304.

The printed wiring board 301 can be provided with a variety of elements such as a resistor, a capacitor, and a semiconductor element. Specifically, the distance (pitch) between electrodes in the input-output terminal portion 106 can be changed to the distance between electrodes in the terminal portion 302, using wirings formed on the printed wiring board 301. Accordingly, even when the electrode pitch in the input-output terminal portion 106 is different from the electrode pitch in the FPC 304, electrical connection between the electrodes in the both can be obtained.

In the display module 300, the FPC 304 may be directly connected to the input-output terminal portion 106 of the display apparatus 100 as illustrated in FIG. 11B. In the case where the pitch of electrodes included in the input-output terminal portion 106 is equal to the pitch of the electrodes included in the FPC 304, the input-output terminal portion 106 may be electrically connected to the FPC 304 without using the printed wiring board 301.

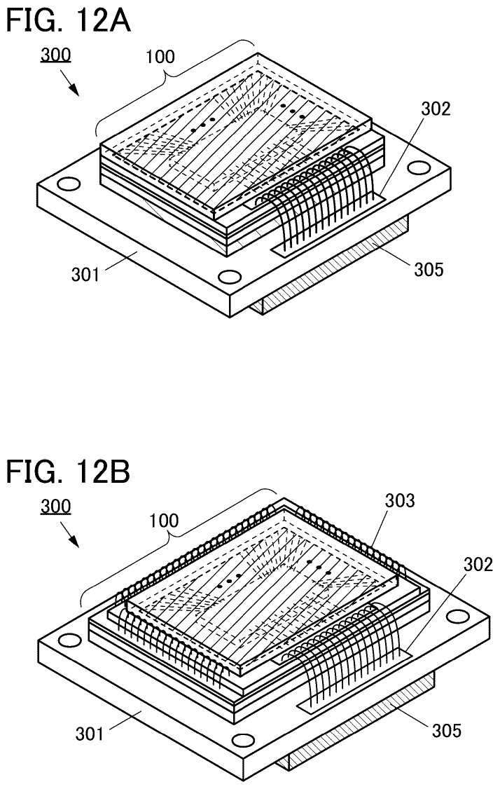

As in the display module 300 illustrated in FIG. 12A, the terminal portion 302 may be electrically connected to a connection portion 305 provided for a bottom surface (a surface where the display apparatus 100 is not provided) of the printed wiring board 301. With the use of a socket-type connection portion as the connection portion 305, for example, the display module 300 can be easily attached to and detached from another device.

As in the display module 300 illustrated in FIG. 12B, a wiring provided in the display portion 104 may be electrically connected to the wiring group 103 through a wire 303. In particular, this is suitable for the case where the display portion 104 is formed using a crystalline silicon wafer (also referred to as a Si wafer).

### <Number of Display Apparatuses 100>

The number of display apparatuses 100 manufactured from one substrate 101 is estimated in the case of using a 12-inch Si wafer as the substrate 101. Table 1 shows specifications used for the estimation.

TABLE 1

| Shot size | 32 mm × 24 mm | |
|---|---|---|
| Marker region (A) | 0.5 | mm |
| Distance between shots (B) | 2 | mm |
| Width of display portion (H) | 31000 | μm |
| Height of display portion (V) | 23000 | μm |
| Pixel size (1 dot) | 2.69 × 8.07 | μm |
| Diagonal size of display portion | 1.53 | inch |

| | |
|---|---|
| Number of display apparatuses | 56 |

Note that the shot size in Table 1 means the size of a region (also referred to as a light-exposure region) that can be processed by one-time light exposure in a photolithography method. The distance between shots is the distance between adjacent light-exposure regions.

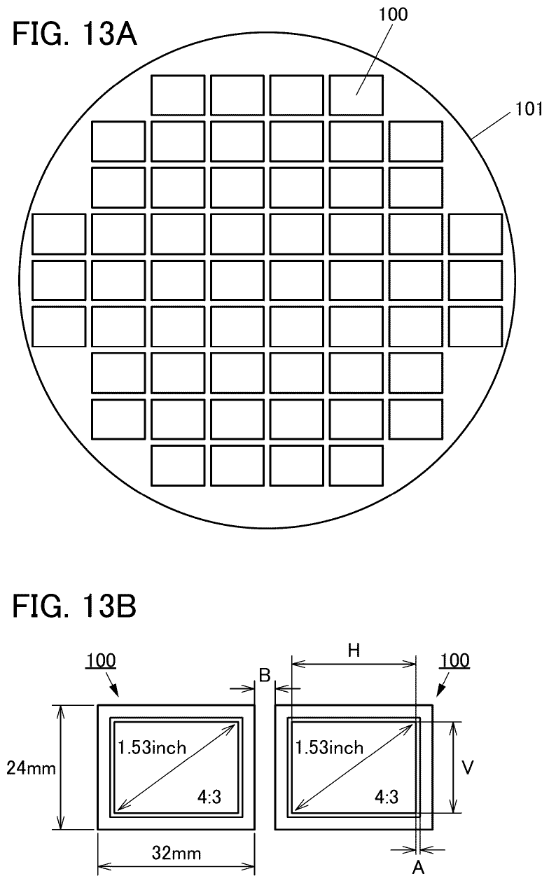

FIG. 13A illustrates a layout of the display apparatus 100 that can be formed over the 12-inch Si wafer serving as the substrate 101. FIG. 13B is a diagram illustrating the correspondence between the specifications in Table 1 and the layout of the display apparatus 100 formed using the 12-inch Si wafer. From one 12-inch Si wafer, 56 display apparatus 100 can be manufactured.

The structures described in this embodiment can be used in an appropriate combination with the structures described in the other embodiments and the like.

### Embodiment 2

In this embodiment, a light-emitting device that can be used for the display element 432 is described.

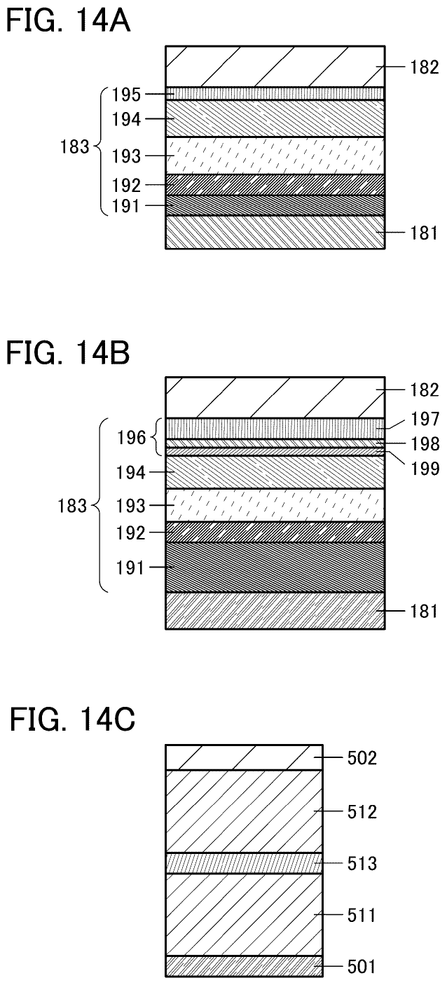

FIG. 14A is a diagram illustrating a light-emitting device. The light-emitting device illustrated in FIG. 14A includes a first electrode 181, a second electrode 182, and an EL layer 183.

For a light-emitting device that can be used in one embodiment of the present invention, typically, a structure obtained with patterning by emission colors (e.g., red (R), green (G), and blue (B)) (also referred to as a side-by-side (SBS) structure)) or a tandem structure (also referred to as a tandem-type element or the like) described later can be employed. The SBS structure is preferred since it can reduce power consumption of the light-emitting device. The tandem structure is preferred since the manufacturing cost of the light-emitting device can be reduced.

The EL layer 183 includes a light-emitting layer 193, and the light-emitting layer 193 contains a light-emitting material. A hole-injection layer 191 and a hole-transport layer 192 are provided between the light-emitting layer 193 and the first electrode 181.

The light-emitting layer 193 may contain a host material in addition to the light-emitting material. The host material is an organic compound having a carrier-transport property. The host material is not limited to one kind of material, and a plurality of kinds of materials may be contained. In such a structure, the plurality of kinds of organic compounds are preferably an organic compound having an electron-transport property and an organic compound having a hole-transport property, in which case the carrier balance in the light-emitting layer 193 can be adjusted. The plurality of organic compounds may be organic compounds each having an electron-transport property, and when the electron-transport properties thereof are different from each other, the electron-transport property of the light-emitting layer 193 can also be adjusted. Proper adjustment of the carrier balance enables a long-life light-emitting device. The plurality of organic compounds that are host materials may form an exciplex, or the host material and the light-emitting material may form an exciplex. The exciplex having an appropriate emission wavelength allows efficient energy transfer to the light-emitting material, providing a light-emitting device with a high efficiency and a long lifetime.

Note that although FIG. 14A illustrates an electron-transport layer 194 and an electron-transport layer 195 in the EL layer 183 in addition to the light-emitting layer 193, the hole-injection layer 191, and the hole-transport layer 192, the structure of the light-emitting device is not limited thereto. Formation of any of these layers may be omitted or a layer having another function may be included.

Next, examples of specific structures and materials of the above light-emitting device are described. The first electrode 181 is preferably formed using a metal, an alloy, or a conductive compound having a high work function (specifically, 4.0 eV or more), a mixture thereof, or the like. Specific examples include indium oxide-tin oxide (ITO: Indium Tin Oxide), indium oxide-tin oxide containing silicon or silicon oxide, indium oxide-zinc oxide, and indium oxide containing tungsten oxide and zinc oxide (IWZO). These conductive metal oxide films are usually formed by a sputtering method but may also be formed by a sol-gel method or the like. Note that when a composite material described later is used for a layer that is in contact with the first electrode 181 in the EL layer 183, an electrode material can be selected regardless of its work function.

Although the EL layer 183 preferably has a stacked-layer structure, there is no particular limitation on the stacked-layer structure, and various layer structures such as a hole-injection layer, a hole-transport layer, a light-emitting layer, an electron-transport layer, an electron-injection layer, a carrier-blocking layer, an exciton-blocking layer, and a charge-generation layer can be employed. In this embodiment, two kinds of structures are described as examples: the structure including the electron-transport layer 194 and the electron-transport layer 195 in addition to the hole-injection layer 191, the hole-transport layer 192, and the light-emitting layer 193 as illustrated in FIG. 14A; and the structure including the electron-transport layer 194 and a charge-generation layer 196 in addition to the hole-injection layer 191, the hole-transport layer 192, and the light-emitting layer 193 as illustrated in FIG. 14B. Materials forming the layers are specifically described below.

The hole-injection layer 191 contains a substance having an acceptor property. Either an organic compound or an inorganic compound can be used as the substance having an acceptor property.

As the substance having an acceptor property, it is possible to use a compound having an electron-withdrawing group (a halogen group or a cyano group); for example, 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), and 2-(7-dicyanomethylene-1,3,4,5,6,8,9,10-octafluoro-7H-pyren-2-ylidene)malononitrile can be given.

As the substance having an acceptor property, molybdenum oxide, vanadium oxide, ruthenium oxide, tungsten oxide, manganese oxide, or the like can be used, other than the above-described organic compounds. Alternatively, the hole-injection layer 191 can be formed using phthalocyanine (abbreviation: H₂Pc), a phthalocyanine complex compound such as copper phthalocyanine (abbreviation: CuPc), an aromatic amine compound, polymer such as poly(3,4-ethylenedioxythiophene)/(polystyrenesulfonicacid) (abbreviation: PEDOT/PSS), or the like. The substance having an acceptor property can extract electrons from an adjacent hole-transport layer (or hole-transport material) by application of an electric field.

Alternatively, a composite material in which a material having a hole-transport property contains the above-described substance having an acceptor property can be used for the hole-injection layer 191. By using a composite material in which a material having a hole-transport property contains an acceptor substance, a material used to form an electrode can be selected regardless of its work function. In other words, besides a material having a high work function, a material having a low work function can also be used for the first electrode 181.

As the material having a hole-transport property used for the composite material, any of a variety of organic compounds such as aromatic amine compounds, carbazole derivatives, aromatic hydrocarbons, and high molecular compounds (e.g., oligomers, dendrimers, or polymers) can be used. Note that the material having a hole-transport property used for the composite material is preferably a substance having a hole mobility higher than or equal to 1×10⁻⁶ cm²/Vs.

Further preferably, the material having a hole-transport property that is used in the composite material is a substance having a relatively deep HOMO level higher than or equal to −5.7 eV and lower than or equal to −5.4 eV. The relatively deep HOMO level of the material having a hole-transport property used for the composite material makes it easy to inject holes into the hole-transport layer 192 and to obtain a light-emitting device with a long lifetime.

The formation of the hole-injection layer 191 can improve the hole-injection property, whereby a light-emitting device having low driving voltage can be obtained. The organic compound having an acceptor property is an easy-to-use material because evaporation is easy and its film can be easily formed.

The hole-transport layer 192 contains a material having a hole-transport property. The material having a hole-transport property preferably has a hole mobility higher than or equal to 1×10⁻⁶ cm²/Vs. Examples of the material having a hole-transport property include 4,4′-bis[N-(1-naphthyl)-N-phenylamino]biphenyl (abbreviation: NPB), N,N-bis(3-methylphenyl)-N,N-diphenyl-[1,1′-biphenyl]-4,4′-diamine (abbreviation: TPD), and 4,4′-bis[N-(spiro-9,9′-bifluoren-2-yl)-N-phenylamino]biphenyl (abbreviation: BSPB). Note that any of the substances given as examples of the material having a hole-transport property that is used for the composite material for the hole-injection layer 191 can also be suitably used as the material included in the hole-transport layer 192.

The light-emitting layer 193 contains a light-emitting substance and a host material. The light-emitting layer 193 may additionally contain other materials. Alternatively, the light-emitting layer 193 may be a stack of two layers with different compositions.

The light-emitting substance may be a fluorescent substance, a phosphorescent substance, a substance exhibiting thermally activated delayed fluorescence (TADF), or another light-emitting substance.

Examples of the material that can be used as a fluorescent substance in the light-emitting layer 193 include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), and N,N-diphenyl-N,N-bis[4-(9-phenyl-9H-fluoren-9-yl)phenyl]pylene-1,6-diamine (abbreviation: 1,6FLPAPrn). Other fluorescent substances can also be used.

In the case where a phosphorescent substance is used as a light-emitting substance in the light-emitting layer 193, examples of the usable material include an organometallic iridium complex including a 4H-triazole skeleton, an organometallic iridium complex including a 1H-triazole skeleton, an organometallic iridium complex including an imidazole skeleton, and an organometallic iridium complex including a phenylpyridine dielectric with an electron-withdrawing group as a ligand. These are compounds exhibiting blue phosphorescent light, and are compounds having an emission wavelength peak at 440 nm to 520 nm.

Other examples include an organometallic iridium complex including a pyrimidine skeleton, an organometallic iridium complex including a pyrazine skeleton, an organometallic iridium complex including a pyridine skeleton, and a rare earth metal complex such as tris(acetylacetonato) (monophenanthroline)terbium(III) (abbreviation: [Tb(acac)₃(Phen)]). These are compounds mainly exhibiting green phosphorescent light, and have an emission wavelength peak at 500 nm to 600 nm. Note that an organometallic iridium complex having a pyrimidine skeleton is particularly preferable because of its distinctly high reliability and emission efficiency.

Other examples include an organometallic iridium complex including a pyrimidine skeleton, an organometallic iridium complex including a pyrazine skeleton, an organometallic iridium complex including a pyridine skeleton, a platinum complex, and a rare earth metal complex. These are compounds exhibiting red phosphorescent light, and have an emission peak at 600 nm to 700 nm. An organometallic iridium complex having a pyrazine skeleton can exhibit red light emission with favorable chromaticity.

Besides the above-described phosphorescent compounds, other known phosphorescent substances may be selected and used.

Examples of the TADF material include a fullerene, a derivative thereof, an acridine, a derivative thereof, and an eosin derivative. Other examples include a metal-containing porphyrin, such as a porphyrin containing magnesium (Mg), zinc (Zn), cadmium (Cd), tin (Sn), platinum (Pt), indium (In), palladium (Pd), or the like.

Note that a TADF material is a material having a small difference between the S1 level and the T1 level and a function of converting triplet excitation energy into singlet excitation energy by reverse intersystem crossing. Thus, a TADF material can upconvert triplet excitation energy into singlet excitation energy (i.e., reverse intersystem crossing) using a small amount of thermal energy and efficiently generate a singlet excited state. In addition, the triplet excitation energy can be converted into light.

An exciplex whose excited state is formed with two kinds of substances has an extremely small difference between the S1 level and the T1 level and functions as a TADF material capable of converting triplet excitation energy into singlet excitation energy.

A phosphorescent spectrum observed at low temperature (e.g., 77 K to 10 K) may be used for an index of the T1 level. When the level of energy with a wavelength of the line obtained by extrapolating a tangent to the fluorescent spectrum at a tail on the short wavelength side is the Si level and the level of energy with a wavelength of the line obtained by extrapolating a tangent to the phosphorescent spectrum at a tail on the short wavelength side is the T1 level, the difference between the S1 level and the T1 level of the TADF material is preferably smaller than or equal to eV, further preferably smaller than or equal to 0.2 eV.

In the case where a TADF material is used as the light-emitting substance, the S1 level of the host material is preferably higher than the Si level of the TADF material. In addition, the T1 level of the host material is preferably higher than the T1 level of the TADF material.

As the host material in the light-emitting layer, various carrier-transport materials such as a material having an electron-transport property, a material having a hole-transport property, and the above-described TADF material can be used.

The material having a hole-transport property is preferably an organic compound having an amine skeleton or a π-electron rich heteroaromatic ring skeleton. Examples include a compound having an aromatic amine skeleton, a compound having a carbazole skeleton, a compound having a thiophene skeleton, and a compound having a furan skeleton. Among the above, the compound having an aromatic amine skeleton and the compound having a carbazole skeleton are preferable because these have favorable reliability, have high hole-transport properties, and contribute to a reduction in driving voltage.

As the material having an electron-transport property, for example, a metal complex or an organic compound having a π-electron deficient heteroaromatic ring skeleton is preferable. Examples of the organic compound having a π-electron deficient heteroaromatic ring skeleton include a heterocyclic compound having a polyazole skeleton, a heterocyclic compound having a diazine skeleton, a heterocyclic compound having a triazine skeleton, and a heterocyclic compound having a pyridine skeleton. Among the above materials, the heterocyclic compound having a diazine skeleton, the heterocyclic compound having a triazine skeleton, and the heterocyclic compound having a pyridine skeleton have high reliability and thus are preferable. In particular, the heterocyclic compound having a diazine (pyrimidine or pyrazine) skeleton has a high electron-transport property and contributes to a reduction in driving voltage.

As the TADF material that can be used as the host material, any of the above materials mentioned as the TADF material can also be used. When the TADF material is used as the host material, triplet excitation energy generated in the TADF material is converted into singlet excitation energy by reverse intersystem crossing and transferred to the light-emitting substance, whereby the emission efficiency of the light-emitting device can be increased.

In the case where a fluorescent substance is used as the light-emitting substance, a material including an anthracene skeleton is suitable as the host material. The use of a substance having an anthracene skeleton as a host material for a fluorescent substance makes it possible to achieve a light-emitting layer with favorable emission efficiency and durability.

The electron-transport layer 194 is a layer containing a substance having an electron-transport property. As the substance having an electron-transport property, it is possible to use any of the above-listed substances having electron-transport properties that can be used as the host material.

The electron mobility of the electron-transport layer 194 in the case where the square root of the electric field strength [V/cm] is 600 is preferably higher than or equal to 1×10⁻⁷ cm²/Vs and lower than or equal to 5×10⁻⁵ cm²/Vs. Lowering the electron-transport property of the electron-transport layer 194 enables control of the amount of electrons injected into the light-emitting layer and can prevent the light-emitting layer from having excess electrons. The electron-transport layer preferably contains a material having an electron-transport property and an alkali metal, an alkali metal itself, a compound thereof, or a complex thereof. This structure is particularly preferable, for a long lifetime can be achieved when the hole-injection layer is formed using a composite material that contains a material having a hole-transport property with a relatively deep HOMO level higher than or equal to −5.7 eV and lower than or equal to −5.4 eV. In this case, the material having an electron-transport property preferably has a HOMO level of −6.0 eV or higher.

As the electron-transport layer 195, a layer containing an alkali metal, an alkaline earth metal, or a compound thereof, such as lithium fluoride (LiF), cesium fluoride (CsF), calcium fluoride (CaF₂), or 8-hydroxyquinolinato-lithium (abbreviation: Liq), may be provided between the electron-transport layer 194 and the second electrode 182. An electride or a layer that is formed using a substance with an electron-transport property and includes an alkali metal, an alkaline earth metal, or a compound thereof can be used as the electron-transport layer 195. Examples of the electride include a substance in which electrons are added at high concentration to an oxide where calcium and aluminum are mixed.

Note that as the electron-transport layer 195, it is possible to use a layer that contains a substance having an electron-transport property (preferably an organic compound having a bipyridine skeleton) and contains a fluoride of the alkali metal or the alkaline earth metal at a concentration higher than or equal to that at which the electron-transport layer 195 becomes in a microcrystalline state (50 wt % or higher). Since the layer has a low refractive index, a light-emitting device having more favorable external quantum efficiency can be provided.

Instead of the electron-transport layer 195, the charge-generation layer 196 may be provided (FIG. 14B). The charge-generation layer 196 refers to a layer capable of injecting holes into a layer in contact therewith on the cathode side and injecting electrons into a layer in contact therewith on the anode side when supplied with a potential. The charge-generation layer 196 includes at least a P-type layer 197. The P-type layer 197 is preferably formed using any of the composite materials given above as examples of the material that can be included in the hole-injection layer 191. The P-type layer 197 may be formed by stacking a film containing the above acceptor material as a material included in the composite material and a film containing the above hole-transport material. When a potential is applied to the P-type layer 197, electrons are injected into the electron-transport layer 194 and holes are injected into the second electrode 182 that is a cathode; thus, the light-emitting device operates. Since the organic compound of one embodiment of the present invention has a low refractive index, the light-emitting device including the organic compound used for the P-type layer 197 can have high external quantum efficiency.

Note that one or both of an electron-relay layer 198 and an electron-injection buffer layer 199 are preferably provided in the charge-generation layer 196 in addition to the P-type layer 197.

The electron-relay layer 198 contains at least a substance having an electron-transport property and has a function of preventing an interaction between the electron-injection buffer layer 199 and the P-type layer 197 to transfer electrons smoothly. The LUMO level of the substance having an electron-transport property contained in the electron-relay layer 198 is preferably between the LUMO level of an acceptor substance in the P-type layer 197 and the LUMO level of a substance contained in a layer of the electron-transport layer 194 in contact with the charge-generation layer 196. A specific energy level of the LUMO level of the substance having an electron-transport property used for the electron-relay layer 198 is higher than or equal to −5.0 eV, preferably higher than or equal to −5.0 eV and lower than or equal to −3.0 eV. Note that as the substance having an electron-transport property used for the electron-relay layer 198, a phthalocyanine-based material or a metal complex having a metal-oxygen bond and an aromatic ligand is preferably used.

For the electron-injection buffer layer 199, a substance having a high electron-injection property, such as an alkali metal, an alkaline earth metal, a rare earth metal, or a compound thereof (an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)), can be used.

In the case where the electron-injection buffer layer 199 contains the substance having an electron-transport property and a donor substance, an organic compound such as tetrathianaphthacene (abbreviation: TTN), nickelocene, or decamethylnickelocene can be used as the donor substance, as well as an alkali metal, an alkaline earth metal, a rare earth metal, or a compound thereof (e.g., an alkali metal compound (including an oxide such as lithium oxide, a halide, and a carbonate such as lithium carbonate and cesium carbonate), an alkaline earth metal compound (including an oxide, a halide, and a carbonate), or a rare earth metal compound (including an oxide, a halide, and a carbonate)). Note that as the substance having an electron-transport property, a material similar to the above-described material included in the electron-transport layer 194 can be used.

As a substance forming the second electrode 182, a metal, an alloy, an electrically conductive compound, or a mixture thereof having a low work function (specifically, 3.8 eV or less) or the like can be used. Specific examples of such a cathode material include elements belonging to Group 1 and Group 2 of the periodic table, such as alkali metals (e.g., lithium (Li) and cesium (Cs)), magnesium (Mg), calcium (Ca), and strontium (Sr), alloys containing any of these elements (e.g., MgAg and AlLi), rare earth metals such as europium (Eu) and ytterbium (Yb), and alloys containing any of these rare earth metals. However, when the electron-injection layer is provided between the second electrode 182 and the electron-transport layer, a variety of conductive materials such as Al, Ag, ITO, and indium oxide-tin oxide containing silicon or silicon oxide can be used for the second electrode 182 regardless of their work functions. A film of such a conductive material can be formed by a dry process such as a vacuum evaporation method or a sputtering method, an ink-jet method, a spin coating method, or the like. Alternatively, a wet process using a sol-gel method or a wet process using a paste of a metal material may be employed for the formation.

Various methods can be used as a method for forming the EL layer 183 regardless of whether it is a dry process or a wet process. For example, a vacuum evaporation method, a gravure printing method, an offset printing method, a screen printing method, an ink-jet method, a spin coating method, or the like may be used.

Different methods may be used to form the electrodes or the layers described above.

Note that the structure of the layers provided between the first electrode 181 and the second electrode 182 is not limited to the above structure. However, a structure is preferable in which a light-emitting region where holes and electrons recombine is provided at a position away from the first electrode 181 and the second electrode 182 so as to prevent quenching caused by the proximity of the light-emitting region and a metal used for the electrodes or the carrier-injection layers.

Furthermore, in order to inhibit energy transfer from an exciton generated in the light-emitting layer, it is preferable to form the hole-transport layer and the electron-transport layer that are in contact with the light-emitting layer 193, particularly a carrier-transport layer closer to the recombination region in the light-emitting layer 193, using a substance having a wider band gap than the band gap of the light-emitting material of the light-emitting layer or the light-emitting material contained in the light-emitting layer.

In the case where the light-emitting device is a top-emission light-emitting element, preferably, the first electrode 181 is formed using a conductive material that efficiently reflects light emitted from the EL layer 183 and the second electrode 182 is formed using a conductive material that transmits visible light. The first electrode 181 may have a stacked-layer structure of multiple layers, without being limited to a single layer. For example, in the case where the first electrode 181 is used as an anode, a layer in contact with the EL layer 183 may be a light-transmitting layer, such as indium tin oxide layer, and a layer having high reflectance (e.g., aluminum, an alloy containing aluminum, or silver) may be provided in contact with the layer.

For the conductive film that reflects visible light, for example, a metal material such as aluminum, gold, platinum, silver, nickel, tungsten, chromium, molybdenum, iron, cobalt, copper, or palladium or an alloy containing any of these metal materials can be used. Lanthanum, neodymium, germanium, or the like may be added to the above metal material and/or alloy. In addition, an alloy containing aluminum (an aluminum alloy) such as an alloy of aluminum and titanium, an alloy of aluminum and nickel, or an alloy of aluminum and neodymium may be used. Moreover, an alloy containing silver such as an alloy of silver and copper, an alloy of silver and palladium, or an alloy of silver and magnesium can be used. An alloy containing silver and copper is preferable because of its high heat resistance. Furthermore, a metal film or an alloy film may be stacked with a metal oxide film. For example, when a metal film or a metal oxide film is stacked on and in contact with an aluminum alloy film, oxidation of the aluminum alloy film can be suppressed. Other examples of the metal film or the metal oxide film include titanium and titanium oxide. As described above, a conductive film having a light-transmitting property and a film containing a metal material may be stacked. For example, a stacked-layer film of silver and indium tin oxide or a stacked-layer film of an alloy of silver and magnesium and indium tin oxide (ITO) can be used.

In the case where the light-emitting device is a bottom-emission light-emitting element, preferably, the first electrode 181 is formed using a conductive material that transmits visible light and the second electrode 182 is formed using a conductive material that reflects visible light. In the case where the light-emitting device is a display apparatus having a dual-emission structure, the first electrode 181 and the second electrode 182 may be formed using a conductive material transmitting visible light.

Next, an embodiment of a light-emitting device with a structure where a plurality of light-emitting units are stacked (also referred to as a stacked-type element or a tandem element) will be described with reference to FIG. 14C. This light-emitting device is a light-emitting device including a plurality of light-emitting units between an anode and a cathode. One light-emitting unit has substantially the same structure as the EL layer 183, which is illustrated in FIG. 14A. In other words, the light-emitting device illustrated in FIG. 14C can be regarded as a light-emitting device including a plurality of light-emitting units, and the light-emitting device illustrated in FIG. 14A or FIG. 14B can be regarded as a light-emitting device including one light-emitting unit.

In FIG. 14C, a first light-emitting unit 511 and a second light-emitting unit 512 are stacked between an anode 501 and a cathode 502, and a charge-generation layer 513 is provided between the first light-emitting unit 511 and the second light-emitting unit 512. The anode 501 and the cathode 502 correspond, respectively, to the first electrode 181 and the second electrode 182 in FIG. 14A, and the same substance as what is given in the description for FIG. 14A can be used. Furthermore, the first light-emitting unit 511 and the second light-emitting unit 512 may have the same structure or different structures.

The charge-generation layer 513 has a function of injecting electrons into one of the light-emitting units and injecting holes into the other of the light-emitting units when a voltage is applied to the anode 501 and the cathode 502. That is, in FIG. 14C, the charge-generation layer 513 can inject electrons into the first light-emitting unit 511 and can inject holes into the second light-emitting unit 512 in the case where a voltage is applied such that the potential of the anode is higher than the potential of the cathode.

The charge-generation layer 513 is preferably formed to have a structure similar to that of the charge-generation layer 196 described with reference to FIG. 14B. A composite material of an organic compound and a metal oxide has an excellent carrier-injection property and an excellent carrier-transport property; thus, low-voltage driving and low-current driving can be achieved. Note that in the case where the anode-side surface of a light-emitting unit is in contact with the charge-generation layer 513, the charge-generation layer 513 can also serve as a hole-injection layer of the light-emitting unit; therefore, a hole-injection layer is not necessarily provided in the light-emitting unit.

In the case where the electron-injection buffer layer 199 is provided in the charge-generation layer 513, the electron-injection buffer layer 199 serves as an electron-injection layer in the light-emitting unit on the anode side; therefore, an electron-injection layer is not necessarily formed in the light-emitting unit on the anode side.

The light-emitting device having two light-emitting units is described with reference to FIG. 14C; however, the same can also be applied to a light-emitting device in which three or more light-emitting units are stacked. With a plurality of light-emitting units partitioned by the charge-generation layer 513 between a pair of electrodes as in the light-emitting device of this embodiment, it is possible to provide a long-life element that can emit high-luminance light with a current density kept low. A light-emitting apparatus which can be driven at low voltage and has low power consumption can be provided.

Furthermore, when emission colors of the light-emitting units are different, light emission of a desired color can be exhibited from the whole light-emitting device. For example, in a light-emitting device having two light-emitting units, emission colors of red and green are exhibited from the first light-emitting unit and an emission color of blue is exhibited from the second light-emitting unit, whereby the light-emitting device that can emit white light as a whole can be provided.

The above-described layers and electrodes such as the EL layer 183, the first light-emitting unit 511, the second light-emitting unit 512, and the charge-generation layer can be formed by a method such as an evaporation method (including a vacuum evaporation method), a droplet discharge method (also referred to as an ink-jet method), a coating method, or a gravure printing method. A low molecular material, a middle molecular material (including an oligomer and a dendrimer), or a high molecular material may be included in the layers or electrodes.

The structures described in this embodiment can be used in an appropriate combination with any of the structures described in the other embodiments and the like.

### Embodiment 3

In this embodiment, examples of an electronic device in which a display apparatus of one embodiment of the present invention can be used will be described.

The display apparatus of one embodiment of the present invention can be used in a display portion of an electronic device. Thus, an electronic device with high display quality can be achieved. An electronic device with an extremely high resolution can be achieved. A highly reliable electronic device can be achieved.

Examples of electronic devices including the display apparatus or the like of one embodiment of the present invention include display apparatuses such as televisions and monitors, lighting devices, desktop or laptop personal computers, word processors, image reproduction devices which reproduce still images or moving images stored in recording media such as DVDs (Digital Versatile Discs), portable CD players, radios, tape recorders, headphone stereos, stereos, table clocks, wall clocks, cordless phone handsets, transceivers, car phones, cellular phones, portable information terminals, tablet terminals, portable game machines, stationary game machines such as pachinko machines, calculators, electronic notebooks, e-book readers, electronic translators, audio input devices, video cameras, digital still cameras, electric shavers, high-frequency heating appliances such as microwave ovens, electric rice cookers, electric washing machines, electric vacuum cleaners, water heaters, electric fans, hair dryers, air-conditioning systems such as air conditioners, humidifiers, and dehumidifiers, dishwashers, dish dryers, clothes dryers, futon dryers, electric refrigerators, electric freezers, electric refrigerator-freezers, freezers for preserving DNA, flashlights, tools such as chain saws, smoke detectors, and medical equipment such as dialyzers. Other examples include industrial equipment such as guide lights, traffic lights, conveyor belts, elevators, escalators, industrial robots, power storage systems, and power storage devices for leveling the amount of power supply and smart grid. In addition, moving objects and the like driven by fuel engines and electric motors using power from power storage units, and the like may also be included in the category of electronic devices. Examples of the moving objects include electric vehicles (EVs), hybrid electric vehicles (HVs) that include both an internal-combustion engine and a motor, plug-in hybrid electric vehicles (PHVs), tracked vehicles in which caterpillar tracks are substituted for wheels of these vehicles, motorized bicycles including motor-assisted bicycles, motorcycles, electric wheelchairs, golf carts, boats, ships, submarines, helicopters, aircraft, rockets, artificial satellites, space probes, planetary probes, and spacecraft.

The electronic device of one embodiment of the present invention may include a secondary battery (battery), and preferably, the secondary battery can be charged by contactless power transmission.

Examples of the secondary battery include a lithium ion secondary battery, a nickel-hydride battery, a nickel-cadmium battery, an organic radical battery, a lead-acid battery, an air secondary battery, a nickel-zinc battery, and a silver-zinc battery.

The electronic device of one embodiment of the present invention may include an antenna. When a signal is received by the antenna, a video, information, and the like can be displayed on a display portion. When the electronic device includes the antenna and a secondary battery, the antenna may be used for contactless power transmission.

The electronic device of one embodiment of the present invention may include a sensor (a sensor having a function of measuring force, displacement, position, speed, acceleration, angular velocity, rotational frequency, distance, light, liquid, magnetism, temperature, a chemical substance, sound, time, hardness, an electric field, current, voltage, power, radioactive rays, flow rate, humidity, a gradient, oscillation, odor, or infrared rays).

The electronic device of one embodiment of the present invention can have a variety of functions. For example, the electronic device can have a function of displaying a variety of data (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Furthermore, an electronic device including a plurality of display portions can have a function of displaying image data mainly on one display portion while displaying text data mainly on another display portion, a function of displaying a three-dimensional image by displaying images on a plurality of display portions with a parallax taken into account, or the like. Furthermore, an electronic device including an image receiving portion can have a function of taking a still image or a moving image, a function of automatically or manually correcting a taken image, a function of storing a taken image in a recording medium (an external recording medium or a recording medium incorporated in the electronic device), a function of displaying a taken image on a display portion, or the like. Note that functions of the electronic device of one embodiment of the present invention are not limited thereto, and the electronic devices can have a variety of functions.

Thus, the display apparatus of one embodiment of the present invention can be suitably used for a portable electronic device, a wearable electronic device (wearable device), an e-book reader, or the like. In addition, the display apparatus can be suitably used for a VR (Virtual Reality) device, an AR (Augmented Reality) device, and the like.

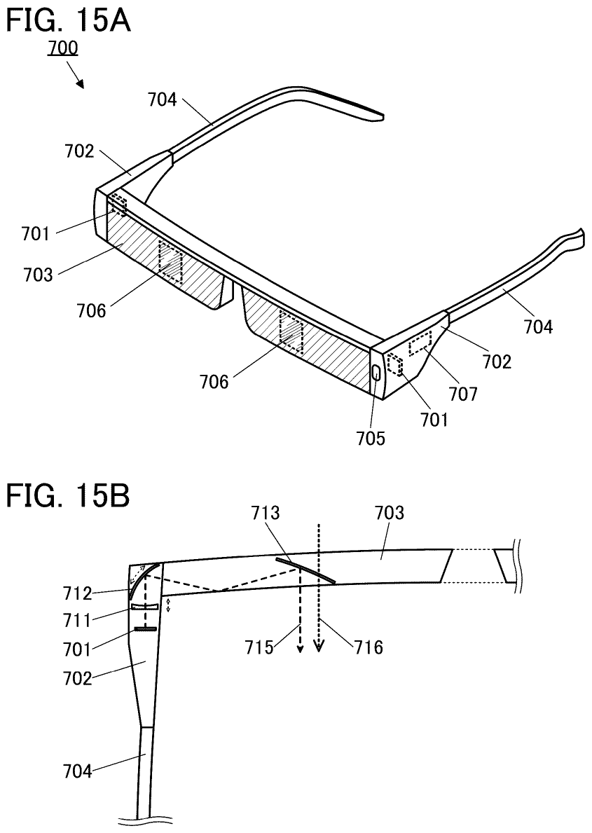

FIG. 15A is a perspective view of an electronic device 700 that is of a glasses type. The electronic device 700 includes a pair of display panels 701, a pair of housings 702, a pair of optical members 703, a pair of temples 704, and the like.

The electronic device 700 can project an image displayed on the display panel 701 onto a display region 706 of the optical member 703. Since the optical members 703 have a light-transmitting property, a user can see images displayed on the display regions 706, which are superimposed on transmission images seen through the optical members 703. Thus, the electronic device 700 is an electronic device capable of AR display.

One housing 702 is provided with a camera 705 capable of capturing images of the front side. Although not illustrated, one of the housings 702 is provided with a wireless receiver or a connector to which a cable can be connected, whereby a video signal or the like can be supplied to the housing 702. Furthermore, when the housing 702 is provided with an acceleration sensor such as a gyroscope sensor, the orientation of the user's head can be detected and an image corresponding to the orientation can be displayed on the display region 706. Moreover, the housing 702 is preferably provided with a battery 707, in which case charging can be performed with or without a wire.

Next, a method for projecting an image on the display region 706 of the electronic device 700 is described with reference to FIG. 15B. The display panel 701, a lens 711, and a reflective plate 712 are provided in the housing 702. A reflective surface 713 functioning as a half mirror is provided in a portion corresponding to the display region 706 of the optical member 703.

Light 715 emitted from the display panel 701 passes through the lens 711 and is reflected by the reflective plate 712 to the optical member 703 side. In the optical member 703, the light 715 is fully reflected repeatedly by end surfaces of the optical member 703 and reaches the reflective surface 713, whereby an image is projected on the reflective surface 713. Accordingly, the user can see both the light 715 reflected by the reflective surface 713 and transmitted light 716 transmitted through the optical member 703 (including the reflective surface 713).

FIG. 15 illustrates an example in which the reflective plate 712 and the reflective surface 713 each have a curved surface. This can increase optical design flexibility and reduce the thickness of the optical member 703, compared to the case where they have flat surfaces. Note that the reflective plate 712 and the reflective surface 713 may be flat.

The reflective plate 712 can use a component having a mirror surface, and preferably has high reflectance. As the reflective surface 713, a half mirror utilizing reflection of a metal film may be used, but the use of prism utilizing total reflection or the like can increase the transmittance of the transmitted light 716.

Here, the housing 702 preferably includes a mechanism for adjusting the distance and angle between the lens 711 and the display panel 701. This enables focus adjustment, zooming in/out of an image, or the like. One or both of the lens 711 and the display panel 701 are preferably configured to be movable in the optical-axis direction, for example.

The housing 702 preferably includes a mechanism capable of adjusting the angle of the reflective plate 712. The position of the display region 706 where images are displayed can be changed by changing the angle of the reflective plate 712. Thus, the display region 706 can be placed at an optimal position in accordance with the position of the user's eye.

The display apparatus of one embodiment of the present invention can be used for the display panel 701. Therefore, the electronic device 700 can have high display quality.

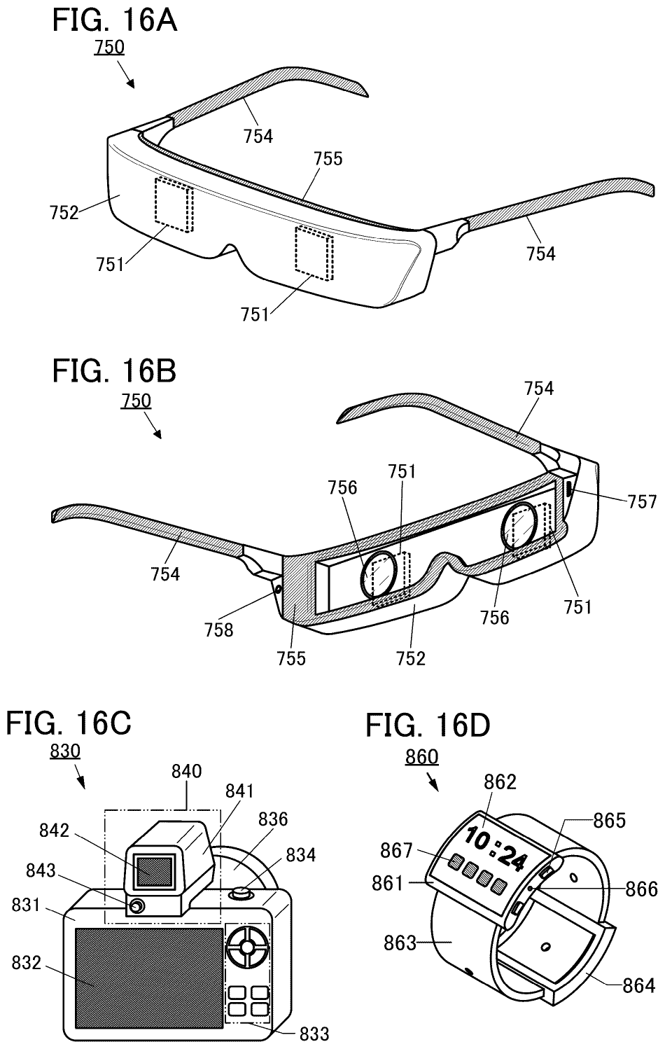

FIG. 16A and FIG. 16B are perspective views of a goggle-type electronic device 750. FIG. 16A is a perspective view illustrating the front surface, the top surface, and the left side surface of the electronic device 750, and FIG. 16B is a perspective view illustrating the back surface, the bottom surface, and the right side surface of the electronic device 750.

The electronic device 750 includes a pair of display panels 751, a housing 752, a pair of temples 754, a cushion 755, a pair of lenses 756, and the like. The pair of display panels 751 is positioned to be seen through the lenses 756 inside the housing 752.

The electronic device 750 is an electronic device for VR. A user wearing the electronic device 750 can view an image displayed on the display panel 751 through the lens 756. Furthermore, when the pair of display panels 751 displays different images, three-dimensional display using parallax can be performed.

An input terminal 757 and an output terminal 758 are provided on the back side of the housing 752. To the input terminal 757, a cable for supplying a video signal from a video output device or the like, power for charging a battery provided in the housing 752, or the like can be connected. The output terminal 758 can function as, for example, an audio output terminal to which earphones, headphones, or the like can be connected. Note that in the case where audio data can be output by wireless communication or sound is output from an external video output device, the audio output terminal is not necessarily provided.

In addition, the housing 752 preferably includes a mechanism for adjusting the left-right positions of the lenses 756 and the display panels 751 so that the lenses 756 and the display panels 751 are positioned optimally so as to match the positions of the user's eyes. Furthermore, a mechanism for adjusting focus by changing the distance between the lens 756 and the display panel 751 is preferably included.

The display apparatus of one embodiment of the present invention can be used for the display panel 751. Therefore, the electronic device 750 can have high display quality. This enables a user to feel high sense of immersion.

The cushion 755 is a portion in contact with the user's face (forehead, cheek, or the like). The cushion 755 is in close contact with the user's face, so that light leakage can be prevented, which increases the sense of immersion. A soft material is preferably used for the cushion 755 so that the cushion 755 is in close contact with the face of the user wearing the electronic device 750. For example, a material such as rubber, silicone rubber, urethane, or sponge can be used. Furthermore, when a sponge or the like whose surface is covered with cloth, leather (natural leather or synthetic leather), or the like is used, a gap is unlikely to be generated between the user's face and the cushion 755, whereby light leakage can be suitably prevented. Furthermore, using such a material is preferable because it has a soft texture and the user does not feel cold when wearing the device in a cold season, for example. The member in contact with user's skin, such as the cushion 755 or the temple 754, is preferably detachable because cleaning or replacement can be easily performed.

FIG. 16C illustrates an appearance of a camera 830 to which a finder 840 is attached.

The camera 830 includes a housing 831, a display portion 832, operation buttons 833, a shutter button 834, and the like. Furthermore, a detachable lens 836 is attached to the camera 830.

Although the lens 836 of the camera 830 here is detachable from the housing 831 for replacement, the lens 836 may be integrated with the housing.

The camera 830 can take images at the press of the shutter button 834. In addition, the display portion 832 has a function of a touch panel, and images can also be taken by the touch on the display portion 832.

The housing 831 of the camera 830 includes a mount including an electrode, so that the finder 840, a stroboscope, or the like can be connected to the housing.

The finder 840 includes a housing 841, a display portion 842, a button 843, and the like.

The housing 841 includes a mount for engagement with the mount of the camera 830 so that the finder 840 can be attached to the camera 830. The mount includes an electrode, and an image or the like received from the camera 830 through the electrode can be displayed on the display portion 842.

The button 843 functions as a power button. The on/off state of the display portion 842 can be switched with the button 843.

The display apparatus of one embodiment of the present invention can be used in the display portion 832 of the camera 830 and the display portion 842 of the finder 840.

Although the camera 830 and the finder 840 are separate and detachable electronic devices in FIG. 16C, a finder including the display apparatus of one embodiment of the present invention may be built into the housing 831 of the camera 830.

FIG. 16D illustrates an example of a watch-type information terminal. An information terminal 860 includes a housing 861, a display portion 862, a band 863, a buckle 864, an operation switch 865, an input/output terminal 866, and the like. In addition, the information terminal 860 includes an antenna, a battery, and the like inside the housing 861. The information terminal 860 is capable of executing a variety of applications such as mobile phone calls, e-mailing, viewing and editing texts, music reproduction, Internet communication, and a computer game.

In addition, the display portion 862 includes a touch sensor, and operation can be performed by touching the screen with a finger, a stylus, or the like. For example, with a touch on an icon 867 displayed on the display portion 862, an application can be started. The operation switches 865 can have a variety of functions such as time setting, power on/off operation, on/off operation of wireless communication, setting and cancellation of a silent mode, and setting and cancellation of a power saving mode. For example, the functions of the operation switches 865 can be set by the operation system incorporated in the information terminal 860.

The information terminal 860 can execute near field communication conformable to a communication standard. For example, mutual communication between the information terminal 860 and a headset capable of wireless communication enables hands-free calling. In addition, the information terminal 860 includes an input/output terminal 866, and can perform data transmission and reception with another information terminal through the input/output terminal 866. In addition, charging can be performed via the input/output terminal 866. Note that the charging operation may be performed by wireless power feeding without using the input/output terminal 866.

The structures described in this embodiment can be used in an appropriate combination with any of the structures described in the other embodiments and the like.

### REFERENCE NUMERALS

100: display apparatus, 101: substrate, 102: driver circuit, 103: wiring group, 104: display portion, 105: substrate, 106: input-output terminal portion, 111: support substrate, 113: memory device, 114: GPU, 115: CPU, 120: semiconductor chip, 121: Si substrate, 122: BOX layer 123: transistor, 124: insulating layer, 125: insulating layer

1. A display apparatus comprising a display portion and a peripheral circuit portion that drives the display portion,
wherein the display portion and the peripheral circuit portion comprise a region overlapping with each other,
wherein the display portion comprises a plurality of pixels arranged in matrix,
wherein the peripheral circuit portion comprises a first transistor,
wherein the pixel comprises a second transistor, and
wherein a composition of a first semiconductor layer included in the first transistor is different from a composition of a second semiconductor layer included in the second transistor.

2. The display apparatus according to claim 1,
wherein the peripheral circuit portion comprises a scan line driver circuit and a signal line driver circuit.

3. The display apparatus according to claim 1,
wherein the plurality of pixels are each configured to emit light, and
wherein the light is emitted in a direction in which the peripheral circuit portion is not formed.

4. The display apparatus according to claim 1,
wherein the pixel comprises an EL element.

5. The display apparatus according to claim 1,
wherein the first semiconductor layer comprises a single crystal semiconductor or a polycrystal semiconductor.

6. The display apparatus according to claim 1,
wherein the first semiconductor layer comprises silicon.

7. The display apparatus according to claim 1,
wherein the second semiconductor layer comprises an oxide semiconductor.

8. The display apparatus according to claim 7,
wherein the second semiconductor layer comprises at least one of indium and zinc.

9. An electronic device comprising the display apparatus according to claim 1, an optical member, and a battery.
